(19) United States
(12) Patent Application Publication
(10) Pub. No.: US 2025/0191618 A1
(43) Pub. Date: Jun. 12, 2025

(54) SEMICONDUCTOR STORAGE DEVICE AND METHOD OF MANUFACTURING SEMICONDUCTOR STORAGE DEVICE

(71) Applicant: Kioxia Corporation, Tokyo (JP)

(72) Inventor: Kosei NODA, Yokkaichi Mie (JP)

(73) Assignee: Kioxia Corporation, Tokyo (JP)

(21) Appl. No.: 19/061,698

(22) Filed: Feb. 24, 2025

Related U.S. Application Data
(63) Continuation of application No. PCT/JP2022/034782, filed on Sep. 16, 2022.

(51) Int. Cl. G11C 5/06; G11C 16/04; H10B 43/10; H10B 43/27; H10B 43/35; H10B 43/40

(52) U.S. Cl. CPC G11C 5/063; G11C 16/0483; H10B 43/10; H10B 43/27; H10B 43/35; H10B 43/40

(57) ABSTRACT

A semiconductor storage device according to an embodiment includes a substrate, a transistor, a multi-layered body, a pillar, and a source line. The transistor is on the substrate. The multi-layered body includes a plurality of gate electrode layers and a plurality of insulating layers alternately stacked one by one in a first direction. The pillar includes an insulating core, a channel layer, and a memory film. The source line is between the multi-layered body and the substrate. The source line extends at least in a second direction. The pillar has a first end and a second end. The first end is in contact with the source line. The second end is on a side opposite to the first end in the first direction. A width of the first end in the second direction is larger than a width of the second end in the second direction.

### CROSS-REFERENCE TO RELATED APPLICATION

This application is a continuation of International Application No. PCT/JP2022/034782, filed Sep. 16, 2022, and the entire contents of which are incorporated herein by reference.

### FIELD

Embodiments of the present invention relate to a semiconductor storage device and a method of manufacturing the semiconductor storage device.

### BACKGROUND ART

A semiconductor storage device having a multi-layered body including word lines and insulating layers alternately stacked, a memory pillar penetrating the multi-layered body, and a source line connected to the memory pillar is known.

### BRIEF DESCRIPTION OF THE DRAWINGS

FIG. 1 is a block diagram showing a part of a configuration of a semiconductor storage device of a first embodiment.

FIG. 2 is a diagram showing an equivalent circuit of a part of a memory cell array of the first embodiment.

FIG. 3 is a cross-sectional view showing a part of the semiconductor storage device of the first embodiment.

FIG. 4 is a cross-sectional view showing a region surrounded by line F4 of the semiconductor storage device shown in FIG. 3.

FIG. 5 is a cross-sectional view along line F5-F5 of the semiconductor storage device shown in FIG. 4.

FIG. 6 is a cross-sectional view showing a region surrounded by line F6 of the semiconductor storage device shown in FIG. 4.

FIG. 7 is a cross-sectional view along line F7-F7 of the semiconductor storage device shown in FIG. 3.

FIG. 8 is a cross-sectional view showing a region surrounded by line F8 of the semiconductor storage device shown in FIG. 7.

FIG. 9 is a diagram showing a flow of a method of manufacturing the semiconductor storage device of the first embodiment.

FIG. 10A is a cross-sectional view showing the method of manufacturing the semiconductor storage device of the first embodiment.

FIG. 10B is a cross-sectional view showing the method of manufacturing the semiconductor storage device of the first embodiment.

FIG. 10C is a cross-sectional view showing the method of manufacturing the semiconductor storage device of the first embodiment.

FIG. 10D is a cross-sectional view showing the method of manufacturing the semiconductor storage device of the first embodiment.

FIG. 10E is a cross-sectional view showing the method of manufacturing the semiconductor storage device of the first embodiment.

FIG. 10F is a cross-sectional view showing the method of manufacturing the semiconductor storage device of the first embodiment.

FIG. 10G is a cross-sectional view showing the method of manufacturing the semiconductor storage device of the first embodiment.

FIG. 10H is a cross-sectional view showing the method of manufacturing the semiconductor storage device of the first embodiment.

FIG. 10I is a cross-sectional view showing the method of manufacturing the semiconductor storage device of the first embodiment.

FIG. 10J is a cross-sectional view showing the method of manufacturing the semiconductor storage device of the first embodiment.

FIG. 10K is a cross-sectional view showing the method of manufacturing the semiconductor storage device of the first embodiment.

FIG. 10L is a cross-sectional view showing the method of manufacturing the semiconductor storage device of the first embodiment.

FIG. 10M is a cross-sectional view showing the method of manufacturing the semiconductor storage device of the first embodiment.

FIG. 10N is a cross-sectional view showing the method of manufacturing the semiconductor storage device of the first embodiment.

FIG. 10O is a cross-sectional view showing the method of manufacturing the semiconductor storage device of the first embodiment.

FIG. 10P is a cross-sectional view showing the method of manufacturing the semiconductor storage device of the first embodiment.

FIG. 11 is a cross-sectional view showing a part of a semiconductor storage device of a second embodiment.

FIG. 12 is a cross-sectional view showing a part of a semiconductor storage device of a third embodiment.

FIG. 13 is a cross-sectional view showing a part of a semiconductor storage device of a fourth embodiment.

FIG. 14 is a diagram showing a flow of a method of manufacturing the semiconductor storage device of the fourth embodiment.

FIG. 15 is a cross-sectional view showing a part of a semiconductor storage device of a fifth embodiment.

FIG. 16 is a plan view showing a part of a semiconductor storage device of a sixth embodiment.

FIG. 17 is a cross-sectional view along line F17-F17 of the semiconductor storage device shown in FIG. 16.

### DETAILED DESCRIPTION

A semiconductor storage device according to an embodiment includes a substrate, a transistor, a multi-layered body, a pillar, and a source line. The transistor is on the substrate. The multi-layered body is on a side opposite to the substrate with respect to the transistor. The multi-layered body includes a plurality of gate electrode layers and a plurality of insulating layers. The plurality of gate electrode layers and the plurality of insulating layers are alternately stacked one by one in a first direction. The pillar extends in the first direction within the multi-layered body. The pillar includes an insulating core, a channel layer, and a memory film. The channel layer is between the plurality of gate electrode layers and the insulating core. The memory film is between the plurality of gate electrode layers and the channel layer. The source line is between the multi-layered body and the substrate. The source line extends at least in a second direction intersecting the first direction. The pillar has a first end and a second end. The first end is in contact with the source line. The second end is on a side opposite to the first end in the first direction. The first end has a width in the second direction. The width of the first end is larger than a width of the second end in the second direction.

Hereinafter, a semiconductor storage device and a method of manufacturing a semiconductor storage device of an embodiment will be described with reference to drawings. In the following description, components having the same or similar functions will be denoted by the same reference signs. Also, duplicate description of the components may be omitted. In the following description, when a reference sign is appended with a number or an alphabetical letter at the end for distinction, the number or the alphabetical letter at the end may be omitted when there is no need for distinguishing. “Parallel”, “orthogonal”, or “the same” may include a case of “substantially parallel”, “substantially orthogonal”, or “substantially the same”. “Connection” is not limited to a case of being mechanically connected, and may also include a case of being electrically connected. That is, “connection” is not limited to a case in which two elements to be connected are directly connected, and may include a case in which the above-described two elements are connected with another element interposed therebetween. “Annular” is not limited to a circular annular shape, and may include a rectangular annular shape or a triangular annular shape. “Adjacent” is not limited to a case in which two elements are in contact with each other, but may also include a case in which two elements are separated from each other (for example, a case in which another element is interposed between the two elements).

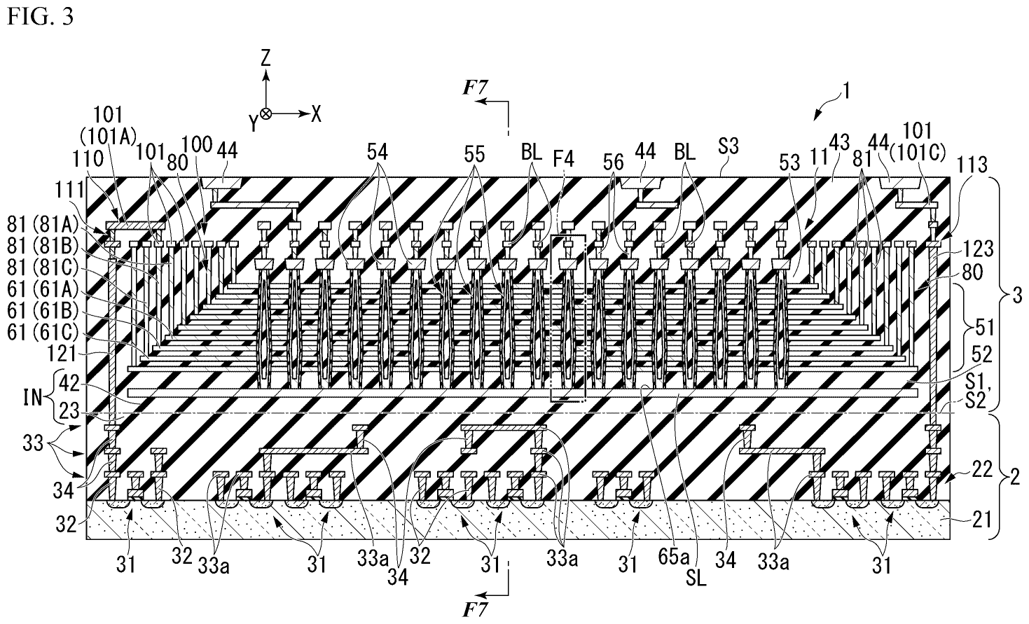

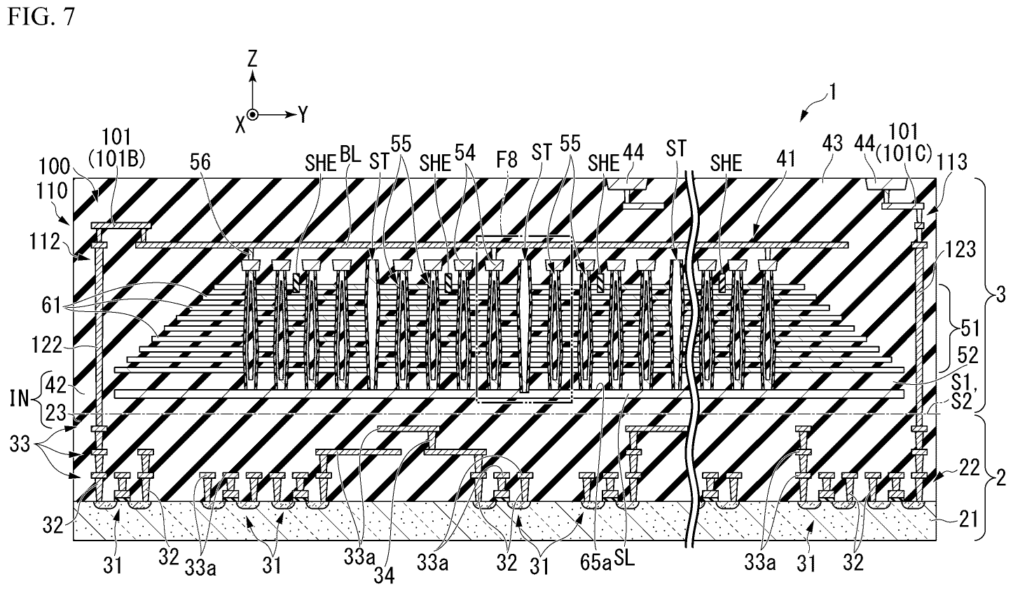

An X direction, a Y direction, and a Z direction will be defined. The +X direction is a direction in which a word line WL (refer to FIG. 3) to be described later extends. The Y direction is a direction intersecting (for example, is orthogonal to) the X direction. The Y direction is a direction in which a bit line BL (refer to FIG. 7) to be described later extends. The Z direction is a direction intersecting (for example, is orthogonal to) the X direction and Y direction. The Z direction is a thickness direction of a semiconductor substrate 21 (refer to FIG. 3) to be described later. In the following description, a side on which a multi-layered body 51 is positioned as viewed from the semiconductor substrate 21 may be referred to as an “upper side” and a side opposite thereto may be referred to as a “lower side”. Also, in the following description, a position in the Z direction may be referred to using a “height”. However, these expressions are used for convenience only and do not define a direction of gravity. The Z direction is an example of a “first direction”. The X direction is an example of a “second direction”. The Y direction is an example of a “third direction”. Note that, in some drawings, for convenience of explanation, the number of conductive layers 61 and the like are simplified.

### First Embodiment

### 1. Configuration of Semiconductor Storage Device

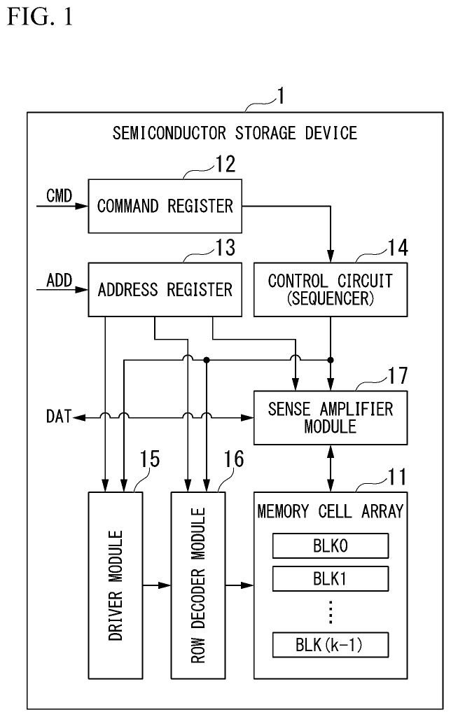

FIG. 1 is a block diagram showing a part of a configuration of a semiconductor storage device 1. The semiconductor storage device 1 is, for example, a nonvolatile semiconductor storage device and is a NAND-type flash memory. The semiconductor storage device 1 can be connected to an external host device and can be used as a storage space for the host device. The semiconductor storage device 1 includes, for example, a memory cell array 11, a command register 12, an address register 13, a control circuit (sequencer) 14, a driver module 15, a row decoder module 16, and a sense amplifier module 17.

The memory cell array 11 includes a plurality of blocks BLK0 to BLK(k−1) (k is an integer of 1 or more). The block BLK is a set of a plurality of memory cell transistors that store data non-volatilely. The block BLK is used as units of data erasure. A plurality of bit lines and a plurality of word lines are provided in the memory cell array 11. Each of the memory cell transistors is associated with one bit line and one word line.

The command register 12 holds a command CMD received by the semiconductor storage device 1 from the host device. The address register 13 holds address information ADD received by the semiconductor storage device 1 from the host device. The control circuit 14 is a circuit configured to control various operations of the semiconductor storage device 1. For example, the control circuit 14 executes a write operation, a read operation, an erase operation, or the like of data based on the command CMD held in the command register 12.

The driver module 15 includes a voltage generation circuit and generates voltages used in various operations of the semiconductor storage device 1. The row decoder module 16 transfers a voltage applied to a signal line corresponding to a selected word line to the selected word line. The sense amplifier module 17 applies a desired voltage to each bit line in the write operation. In the read operation, the sense amplifier module 17 determines a data value stored in each memory cell transistor based on a voltage of each bit line, and transfers the determination result to the host device as read data DAT.

### 2. Electrical Configuration of Memory Cell Array

Next, an electrical configuration of the memory cell array 11 will be described.

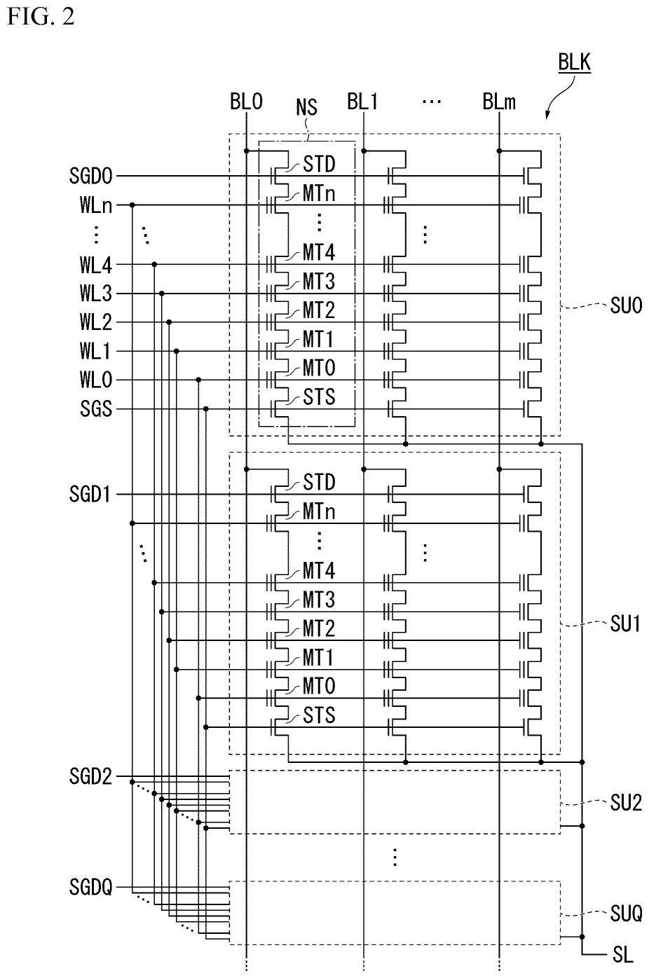

FIG. 2 is a diagram showing an equivalent circuit of a part of the memory cell array 11. FIG. 2 shows one block BLK included in the memory cell array 11. The block BLK includes a plurality of (for example, four) string units SU0 to SUQ (Q is an integer of 1 or more).

Each of the string units SU includes a plurality of NAND strings NS that are respectively associated with bit lines BL0 to BLm (m is an integer of 1 or more). Each NAND string NS includes, for example, a plurality of memory cell transistors MT0 to MTn (n is an integer of 1 or more), one or more drain-side selection transistors STD, and one or more source-side selection transistors STS.

In each NAND string NS, the memory cell transistors MT0 to MTn are connected in series. Each of the memory cell transistors MT includes a control gate and a charge storage portion. The control gate of the memory cell transistor MT is connected to one of word lines WL0 to WLn. In each memory cell transistor MT, charge is stored in the charge storage portion according to a voltage applied to the control gate via the word line WL, and a data value is held non-volatilely.

A drain of the drain-side selection transistor STD is connected to the bit line BL corresponding to the NAND string NS. A source of the drain-side selection transistor STD is connected to one end of the memory cell transistors MT0 to MTn connected in series. A control gate of the drain-side selection transistor STD is connected to any one of the drain-side selection gate lines SGD0 to SGDQ. The drain-side selection transistor STD is electrically connected to the row decoder module 16 via the drain-side selection gate line SGD. The drain-side selection transistor STD connects the NAND string NS and the bit line BL when a predetermined voltage is applied to the corresponding drain-side selection gate line SGD.

A drain of the source-side selection transistor STS is connected to the other end of the memory cell transistors MT0 to MTn connected in series. A source of the source-side selection transistor STS is connected to a source line SL. A control gate of the source-side selection transistor STS is connected to a source-side selection gate line SGS. The source-side selection transistor STS connects the NAND string NS and the source line SL when a predetermined voltage is applied to the source-side selection gate line SGS.

In the same block BLK, the control gates of the memory cell transistors MT0 to MTn are commonly connected to the corresponding word lines WL0 to WLn, respectively. The control gates of the drain-side selection transistors STD, each provided in the string units SU0 to SUQ, are commonly connected to the corresponding drain-side selection gate lines SGD0 to SGDQ, respectively. The control gates of the source-side selection transistors STS are commonly connected to the source-side selection gate line SGS. In the memory cell array 11, the bit line BL is shared by the NAND strings NS to which the same column address is assigned in each of the string units SU.

### 3. Physical Configuration of Semiconductor Storage Device

Next, a physical configuration of the semiconductor storage device 1 will be described.

FIG. 3 is a cross-sectional view showing a part of the semiconductor storage device 1. The semiconductor storage device 1 includes, for example, a first chip 2, a second chip 3, and an electrical connection portion 110.

### 3.1 First Chip

First, the first chip 2 will be described. The first chip 2 is a circuit chip including a peripheral circuit 22. The first chip 2 includes, for example, the semiconductor substrate 21, the peripheral circuit 22, and a first insulating portion 23.

The semiconductor substrate 21 is for example, a substrate that serves as a base of the first chip 2. At least a part of the semiconductor substrate 21 has a plate shape extending in the X direction and the Y direction. The semiconductor substrate 21 is formed of, for example, a semiconductor material such as silicon. The semiconductor substrate 21 is an example of a “substrate”.

The peripheral circuit 22 is a circuit configured to operate the memory cell array 11 described above. The peripheral circuit 22 includes one or more of the command register 12, the address register 13, the control circuit 14, the driver module 15, the row decoder module 16, and the sense amplifier module 17 described above. The peripheral circuit 22 includes, for example, a complementary metal oxide semiconductor (CMOS) circuit. The peripheral circuit 22 includes, for example, a plurality of transistors 31, a plurality of contacts 32, a plurality of interconnection layers 33, and a plurality of vias 34.

The plurality of transistors 31 are provided on the semiconductor substrate 21. The transistor 31 is, for example, a field effect transistor. In the present embodiment, the transistor 31 is a metal oxide semiconductor field effect transistor (MOSFET). The transistor 31 includes, for example, a source region and a drain region formed on an upper surface portion of the semiconductor substrate 21.

The plurality of contacts 32 have conductivity and extend in the Z direction. Each of the contacts 32 is in contact with a source region, a drain region, or a gate electrode of the transistor 31. The plurality of interconnection layers 33 are disposed above the plurality of transistors 31. The plurality of interconnection layers 33 are separately disposed at a plurality of heights. Each of the interconnection layers 33 includes a plurality of interconnections 33a extending in the X direction or the Y direction. The plurality of interconnections 33a each include an interconnection 33a connected to the contact 32. Each via 34 extends in the Z direction and connects two interconnections 33a disposed at different heights.

The first insulating portion 23 is an insulating portion provided on the semiconductor substrate 21. The first insulating portion 23 covers the plurality of transistors 31, the plurality of contacts 32, the plurality of interconnection layers 33, and the plurality of vias 34. The first insulating portion 23 is formed of an insulating material such as, for example, silicon oxide. The first insulating portion 23 is formed of, for example, a silicon oxide deposited using tetraethyl orthosilicate (TEOS, Si(OC₂H₅)₄) gas. The first insulating portion 23 has a first surface (first bonding surface) S1 that is bonded to the second chip 3. In the present embodiment, the first surface S1 does not have a metal pad (for example, a copper pad) bonded to the second chip 3.

### 3.2 Second Chip

Next, the second chip 3 will be described. The second chip 3 is an array chip that includes the memory cell array 11. The second chip 3 includes, for example, the memory cell array 11, an upper layer interconnection portion 100, a second insulating portion 42, a third insulating portion 43, and a plurality of pads 44. Here, the second insulating portion 42, the third insulating portion 43, and the plurality of pads 44 will be described, and the memory cell array 11 and the upper layer interconnection portion 100 will be described later.

The second insulating portion 42 is an insulating portion that forms part of an outer periphery of the second chip 3. The second insulating portion 42 covers a lower part of the memory cell array 11. The second insulating portion 42 is formed of an insulating material such as, for example, silicon oxide. The second insulating portion 42 is formed of, for example, a silicon oxide deposited using TEOS gas. The second insulating portion 42 has a second surface (second bonding surface) S2 that is bonded to the first chip 2. In the present embodiment, a metal pad (for example, a copper pad) bonded to the first chip 2 is not present on the second surface S2.

In the present embodiment, the second surface S2 of the second insulating portion 42 is bonded to the first surface S1 of the first insulating portion 23 of the first chip 2. For example, the first surface S1 of the first insulating portion 23 and the second surface S2 of the second insulating portion 42 are overlapped, heated to a predetermined temperature, and pressurized, and thereby the first insulating portion 23 and the second insulating portion 42 are integrated into a single member. Therefore, the first chip 2 and the second chip 3 are bonded together. After the first chip 2 and the second chip 3 are bonded together, a boundary between the first insulating portion 23 and the second insulating portion 42 disappears. As a result, the first insulating portion 23 and the second insulating portion 42 exist as a single insulating portion IN.

The third insulating portion 43 is an insulating portion that forms another part of the outer periphery of the second chip 3. The third insulating portion 43 covers an upper part of the memory cell array 11. The third insulating portion 43 is formed of an insulating material such as, for example, silicon oxide. The third insulating portion 43 is formed of, for example, a silicon oxide deposited using TEOS gas. The third insulating portion 43 has a third surface S3 positioned on a side opposite to the second surface S2.

The pads 44 are pads exposed to the outside of the semiconductor storage device 1 for external connection. The plurality of pads 44 are provided, for example, on the third surface S3 of the third insulating portion 43. The pads 44 are pads for, for example, a signal input, a signal output, signal input/output, or power supply.

### 4. Physical Configuration of Memory Cell Array

Next, a physical configuration of the memory cell array 11 will be described.

As shown in FIG. 3, the memory cell array 11 includes a multi-layered body 51, an insulating layer 52, an insulating layer 53, a source line SL, a plurality of upper contacts 54, a plurality of memory pillars 55, a plurality of bit lines BL, a plurality of contacts 56, a plurality of contacts 81, a plurality of dividing portions ST (refer to FIG. 7), and a plurality of upper dividing portions SHE (refer to FIG. 7).

### 4.1 Multi-Layered Body

First, the multi-layered body 51 will be described. The multi-layered body 51 is disposed on a side opposite to the semiconductor substrate 21 with respect to the plurality of transistors 31.

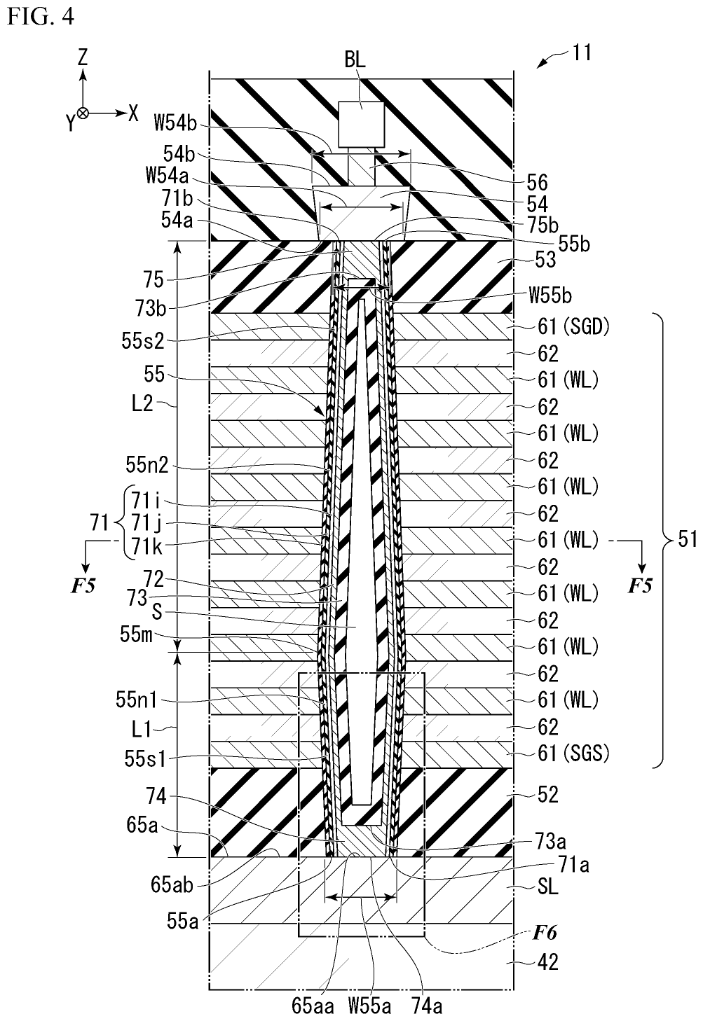

FIG. 4 is a cross-sectional view showing a region surrounded by line F4 of the memory cell array 11 shown in FIG. 3. The multi-layered body 51 includes a plurality of conductive layers 61 and a plurality of insulating layers 62. The plurality of conductive layers 61 and the plurality of insulating layers 62 are alternately stacked one by one in the Z direction.

The conductive layer 61 has a layer shape extending in the X direction and Y direction. Each conductive layer 61 is formed of a conductive material such as, for example, tungsten. The conductive layer 61 is an example of a “gate electrode layer”.

Of the plurality of conductive layers 61, one or more (for example, a plurality of) conductive layers 61 disposed on an uppermost side function as the drain-side selection gate line SGD. The drain-side selection gate line SGD is commonly provided for the plurality of memory pillars 55 aligned in the X direction or the Y direction. A portion in which the drain-side selection gate line SGD and the channel layer 72 (to be described later) of each memory pillar 55 intersect functions as the drain-side selection transistor STD described above.

Of the plurality of conductive layers 61, one or more (for example, a plurality of) conductive layers 61 positioned on a lower side function as the source-side selection gate line SGS. The source-side selection gate line SGS is commonly provided for the plurality of memory pillars 55 aligned in the X direction or the Y direction. A portion in which the source-side selection gate line SGS and the channel layer 72 of each memory pillar 55 intersect functions as the source-side selection transistor STS described above.

Of the plurality of conductive layers 61, the remaining conductive layers 61 sandwiched between the conductive layers 61 functioning as the drain-side selection gate lines SGD or the source-side selection gate lines SGS function as the word lines WL. The word lines WL are each commonly provided for the plurality of memory pillars 55 aligned in the X direction and Y direction. In the present embodiment, a portion in which the word line WL and the channel layer 72 of each memory pillar 55 intersect functions as the memory cell transistor MT. The memory cell transistor MT will be described in detail later.

The insulating layer 62 is an interlayer insulating film provided between two conductive layers 61 adjacent to each other in the Z direction, and insulates the two conductive layers 61. The insulating layer 62 has a layer shape extending in the X direction and Y direction. The insulating layer 62 is formed of an insulating material such as silicon oxide.

### 4.2 Insulating Layer

The insulating layer 52 is an insulating layer disposed between the multi-layered body 51 and the source line SL. The insulating layer 52 is formed of an insulating material such as, for example, silicon oxide. The insulating layer 52 is formed of, for example, silicon oxide deposited using TEOS gas. For example, a thickness in the Z direction of the insulating layer 52 is preferably larger than a thickness in the Z direction of the insulating layer 62 included in the multi-layered body 51.

### 4.3 Insulating Layer

The insulating layer 53 is an insulating layer disposed above the multi-layered body 51. The insulating layer 53 is formed of an insulating material such as, for example, silicon oxide. The insulating layer 53 is formed of, for example, silicon oxide deposited using TEOS gas. For example, a thickness in the Z direction of the insulating layer 53 is larger than a thickness in the Z direction of the insulating layer 62 included in the multi-layered body 51.

### 4.4 Source Line

The source line SL is disposed between the multi-layered body 51 and the semiconductor substrate 21. From another perspective, the source line SL is disposed between the memory pillar 55 (to be described later) and the semiconductor substrate 21. The source line SL extends at least in the second direction. The source line SL is formed of a conductive material. For example, the source line SL contains at least one of silicon and tungsten. In the present embodiment, as will be described in detail later, a copper pad and a copper interconnection are not present during a process of forming the source line SL. Therefore, a heat treatment or the like can be performed without concern for diffusion of the copper material. For example, if the source line SL is formed of silicon, it is possible to perform a heat treatment for the source line SL at a required temperature, thereby crystallizing the silicon of the source line SL to form polysilicon. Therefore, conductivity of the source line SL and connectivity to the memory pillar 55 are enhanced.

In the present embodiment, the source line SL is a plate-shaped conductive layer extending in the X direction and Y direction (refer to FIGS. 3 and 7). For example, the source line SL extends across below the plurality of memory pillars 55 aligned in the X direction and the plurality of memory pillars 55 aligned in the Y direction. In the present embodiment, the source line SL has an upper surface (joining surface) 65a with which lower ends of the plurality of memory pillars 55 are in contact. The upper surface 65a extends in the X direction and Y direction. The upper surface 65a has a first portion 65aa positioned on a lower side of the memory pillar 55 and a second portion 65ab positioned outside the lower side of the memory pillar 55. The second portion 65ab is positioned on a lower side of the plurality of conductive layers 61. The first portion 65aa and the second portion 65ab are positioned on the same plane.

### 4.5 Upper Contact

The upper contact (upper connection portion) 54 is disposed on a side opposite to the source line SL with respect to the multi-layered body 51. From another perspective, the upper contact 54 is disposed on a side opposite to the source line SL with respect to the memory pillar 55. The upper contact 54 is a conductive connection portion for connecting the memory pillar 55 and the bit line BL.

The upper contact 54 has a lower end 54a and an upper end 54b. The lower end 54a is in contact with the memory pillar 55. The upper end 54b is positioned on a side opposite to the lower end 54a in the Z direction. In the present embodiment, the upper contact 54 has an inverted truncated cone shape. An outer diameter (that is, a width in the X direction or Y direction) of the upper contact 54 decreases downward. A width W54a of the lower end 54a in the X direction is smaller than a width W54b of the upper end 54b in the X direction.

### 4.6 Memory Pillar

Next, the memory pillar 55 will be described. The memory pillar 55 extends in the Z direction and penetrates the multi-layered body 51 and the insulating layers 52 and 53. The memory pillar 55 has, for example, a columnar shape or a truncated cone shape. In the present application, the terms “columnar shape” and “truncated cone shape” may include a case in which a maximum outer diameter portion is positioned at an intermediate portion in the Z direction. The memory pillar 55 is an example of a “pillar”.

The memory pillar 55 has a lower end 55a and an upper end 55b. The lower end 55a is in contact with the source line SL. The upper end 55b is positioned on a side opposite to the lower end 55a in the Z direction. The upper end 55b is in contact with the upper contact 54. In the present embodiment, a width W55a of the lower end 55a in the X direction is larger than a width W55b of the upper end 55b in the X direction. The lower end 55a is an example of a “first end”. The upper end 55b is an example of a “second end”. Here, the width W55a of the lower end 55a may be defined as, for example, a width in the X direction of a portion 55s1 of the memory pillar 55 that faces a lowermost conductive layer 61 among the plurality of conductive layers 61. Also, the width W55b of the upper end 55b may be defined as, for example, a width in the X direction of a portion 55s2 of the memory pillar 55 that faces an uppermost conductive layer 61 among the plurality of conductive layers 61. Therefore, “the width W55a in the X direction of the lower end 55a of the memory pillar 55 is larger than the width W55b in the X direction of the upper end 55b of the memory pillar 55” means, for example, that a width in the X direction of the portion 55s1 of the memory pillar 55 is larger than a width in the X direction of the portion 55s2 of the memory pillar 55.

In the present embodiment, the memory pillar 55 has a maximum outer diameter portion (maximum width portion) 55m, a first portion 55n1, and a second portion 55n2. The maximum outer diameter portion 55m is a portion of the memory pillar 55 whose outer diameter (that is, a width in the X direction or Y direction) is the largest. In the present embodiment, the maximum outer diameter portion 55m is positioned below a center of the memory pillar 55 in the Z direction.

The first portion 55n1 is a diameter reducing portion positioned between the lower end 55a and the maximum outer diameter portion 55m. An outer diameter of the memory pillar 55 reduces downward in the first portion 55n1. The second portion 55n2 is a diameter expanding portion positioned between the upper end 55b and the maximum outer diameter portion 55m. An outer diameter of the memory pillar 55 increases downward in the second portion 55n2. In the present embodiment, a length L2 of the second portion 55n2 in the Z direction is larger than a length L1 of the first portion 55n1 in the Z direction.

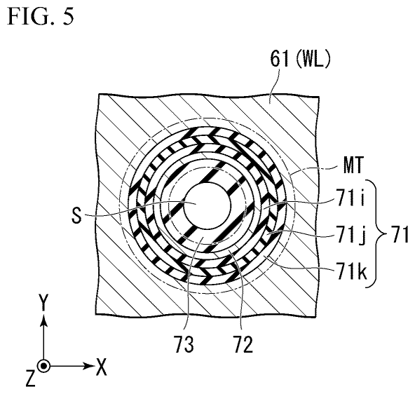

FIG. 5 is a cross-sectional view along line F5-F5 of the memory cell array 11 shown in FIG. 4. The memory pillar 55 includes, for example, a memory film (multilayer film) 71, the channel layer 72, an insulating core 73, a first cap portion 74 (refer to FIG. 4), and a second cap portion 75 (refer to FIG. 4).

The memory film 71 is provided on an outer circumferential side of the channel layer 72. The memory film 71 is positioned between the plurality of conductive layers 61 and the channel layer 72. The memory film 71 includes, for example, a tunnel insulating film 71i, a charge trap film 71j, and a block insulating film 71k.

The tunnel insulating film 71i is provided between the channel layer 72 and the charge trap film 71j. The tunnel insulating film 71i has, for example, an annular shape along an outer circumferential surface of the channel layer 72. The tunnel insulating film 71i extends in the Z direction along the channel layer 72. For example, the tunnel insulating film 71i is provided over the entire length of the memory pillar 55 in the Z direction. The tunnel insulating film 71i is a potential barrier between the channel layer 72 and the charge trap film 71j. The tunnel insulating film 71i contains silicon oxide, or silicon oxide and silicon nitride.

The charge trap film 71j is provided on an outer circumferential side of the tunnel insulating film 71i. The charge trap film 71j is positioned between the tunnel insulating film 71i and the block insulating film 71k. The charge trap film 71j extends in the Z direction, for example, over the entire length of the memory pillar 55 in the Z direction. The charge trap film 71j is a functional film that has a large number of crystal defects (trapping levels) and is capable of trapping charges in the crystal defects. The charge trap film 71j is formed of, for example, silicon nitride. A portion of the charge trap film 71j adjacent to each word line WL is an example of a “charge storage portion” capable of storing information by storing charges.

The block insulating film 71k is provided on an outer circumferential side of the charge trap film 71j. The block insulating film 71k is positioned between the plurality of conductive layers 61 and the charge trap film 71j. The block insulating film 71k is an insulating film that suppresses back tunneling. Back tunneling is a phenomenon in which charges are injected from the word line WL into the charge trap film 71j. The block insulating film 71k extends in the Z direction over the entire length of the memory pillar 55 in the Z direction. The block insulating film 71k is a stacked structure film. A plurality of insulating films such as, for example, silicon oxide films or metal oxide films are stacked in the stacked structure film. An example of the metal oxide is aluminum oxide. The block insulating film 71k may contain a high dielectric constant material (high-k material) such as silicon nitride or hafnium oxide.

The channel layer 72 is provided inside the memory film 71. The channel layer 72 is formed in an annular shape. The channel layer 72 extends in the Z direction, for example, over the entire length of the memory pillar 55 in the Z direction. The channel layer 72 is formed of a semiconductor material such as polysilicon. The channel layer 72 may be doped with impurities. When a voltage is applied to the word line WL, the channel layer 72 electrically connects the bit line BL and the source line SL by forming a channel.

Therefore, a metal-Al-nitride-oxide-silicon (MANOS) type memory cell transistor MT is formed at the same height as each word line WL by an end part of the word line WL adjacent to the memory pillar 55, the block insulating film 71k, the charge trap film 71j, the tunnel insulating film 71i, and the channel layer 72. Note that, the memory film 71 may have a floating gate type charge storage portion (floating gate electrode) as a charge storage portion instead of the charge trap film 71j. The floating gate electrode is formed of, for example, polysilicon containing impurities.

The insulating core 73 is provided inside the channel layer 72. A part of the inside of the channel layer 72 is filled with the insulating core 73. The insulating core 73 is formed of an insulating material such as silicon oxide. A part of the insulating core 73 is formed in an annular shape along an inner circumferential surface of the channel layer 72 and may have a space portion (air gap) S therein.

As shown in FIG. 4, the insulating core 73 extends over most of the memory pillar 55 in the Z direction excluding an upper end part and a lower end part of the memory pillar 55. In the present embodiment, a lower end 73a of the insulating core 73 is spaced apart from the source line SL and positioned above the source line SL. Similarly, an upper end 73b of the insulating core 73 is spaced apart from the upper contact 54 and positioned below the upper contact 54.

The first cap portion 74 is provided at a lower end part of the memory pillar 55. The first cap portion 74 is disposed at least between the insulating core 73 and the source line SL. For example, the first cap portion 74 is disposed between the lower end 73a of the insulating core 73 and the source line SL. The first cap portion 74 is provided on an inner circumferential side of the memory film 71 and is connected to the channel layer 72. Note that, the first cap portion 74 and the source line SL may be formed at the same time by the same process. The first cap portion 74 contains polysilicon doped with impurities. The first cap portion 74 is doped with impurities and then heat-treated to activate and diffuse the impurities. The first cap portion 74 is an example of a “first connection portion”. The impurities include, for example, phosphorus, arsenic, or antimony, but are not limited thereto.

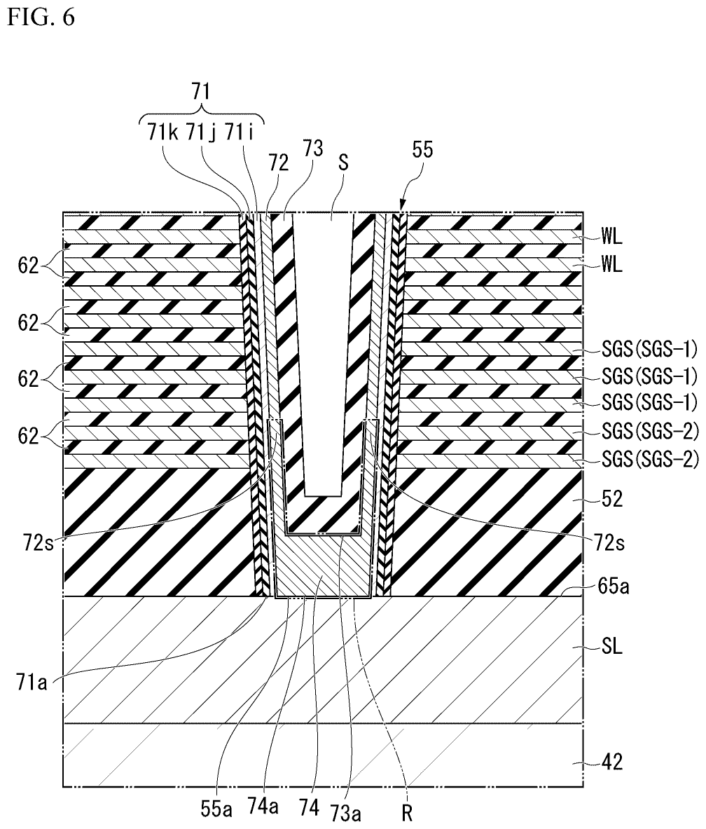

FIG. 6 is a cross-sectional view showing a region surrounded by line F6 of the memory cell array 11 shown in FIG. 4. In the present embodiment, one or more source-side selection gate lines SGS described above include one or more (for example, a plurality of) first source-side selection gate lines SGS-1 and one or more (for example, a plurality of) second source-side selection gate lines SGS-2. The second source-side selection gate lines SGS-2 are disposed between the first source-side selection gate lines SGS-1 and the source line SL.

The first source-side selection gate line SGS-1 is a conductive layer to which a predetermined voltage (first voltage) is applied when the NAND string NS and the source line SL are electrically connected. The second source-side selection gate line SGS-2 is a conductive layer to which a predetermined voltage (first voltage) is applied when the NAND string NS and the source line SL are electrically connected. In addition, the second source-side selection gate line SGS-2 is a conductive layer to which a predetermined high voltage (a second voltage higher than the first voltage) is applied when a data value written in the memory cell transistor MT included in the NAND string NS is erased. For example, when the predetermined high voltage is applied to the second source-side selection gate line SGS-2, holes are generated in the channel layer 72 due to gate-induced drain leakage (GIDL), and charges stored in the memory cell transistor MT are extracted by the generated holes. Therefore, the memory cell transistor MT is brought into an erased state.

In the present embodiment, impurities doped in the first cap portion 74 are diffused by the heat treatment. For example, a region R surrounded by the double-dotted-dashed line in FIG. 6 indicates a region in which impurities are diffused by the heat treatment of the first cap portion 74. In the present embodiment, some of the impurities are diffused by the heat treatment and are thereby contained in a portion 72s of the channel layer 72 adjacent to the second source-side selection gate line SGS-2. According to such a configuration, holes due to GIDL are more likely to be generated in the channel layer 72 during the data erase operation.

### Connection Structure Between Memory Pillar and Source Line

Next, a connection structure between the memory pillar 55 and the source line SL will be described.

In the present embodiment, the memory film 71 (for example, each of the tunnel insulating film 71i, the charge trap film 71j, and the block insulating film 71k) extends in the Z direction within the memory pillar 55 and reaches the upper surface 65a of the source line SL. A lower end 71a of the memory film 71 (for example, a lower end of the tunnel insulating film 71i, a lower end of the charge trap film 71j, and a lower end of the block insulating film 71k) is in contact with the upper surface 65a of the source line SL. On the other hand, the memory film 71 does not protrude into the source line SL. That is, the memory film 71 does not protrude below the upper surface 65a of the source line SL (that is, to the side of the semiconductor substrate 21).

In the present embodiment, a lower end 74a of the first cap portion 74 is positioned on the same plane as the lower end 71a of the memory film 71. The lower end 74a of the first cap portion 74 is in contact with the upper surface 65a of the source line SL. Therefore, the first cap portion 74 and the source line SL are electrically connected. The first cap portion 74 does not protrude into the source line SL. Note that, the first cap portion 74 and the source line SL may be formed at the same time by the same process. In this case, the first cap portion 74 and the source line SL are integrally formed.

Note that, the connection structure between the memory pillar 55 and the source line SL is not limited to the above-described example. For example, if the source line SL is made of a metal, a connection structure between the memory pillar 55 and the source line SL may be a Schottky junction. For example, impurities are implanted in advance into an upper surface portion of the first cap portion 74, and a metal material for forming the source line SL is supplied onto the first cap portion 74, thereby realizing a connection structure using the Schottky junction.

Next, returning to FIG. 4, the second cap portion 75 will be described.

The second cap portion 75 is provided on the upper end part of the memory pillar 55. The second cap portion 75 is disposed at least between the insulating core 73 and the upper contact 54. For example, the second cap portion 75 is disposed between the upper end 73b of the insulating core 73 and the upper contact 54. The second cap portion 75 is provided on the inner circumferential side of the memory film 71 and is formed integrally with the channel layer 72. The second cap portion 75 includes polysilicon doped with impurities. The second cap portion 75 is doped with impurities and then heat-treated to diffuse the impurities. The second cap portion 75 is an example of a “second connection portion”.

### Connection Structure Between Memory Pillar and Upper Contact

Next, the connection structure between the memory pillar 55 and the upper contact 54 will be described.

In the present embodiment, the memory film 71 (for example, each of the tunnel insulating film 71i, the charge trap film 71j, and the block insulating film 71k) extends in the Z direction within the memory pillar 55 and reaches the upper contact 54. An upper end 71b of the memory film 71 (for example, an upper end of the tunnel insulating film 71i, an upper end of the charge trap film 71j, and an upper end of the block insulating film 71k) is in contact with the lower surface 54a of the upper contact 54. On the other hand, the memory film 71 does not protrude into the upper contact 54.

In the present embodiment, an upper end 75b of the second cap portion 75 is positioned on the same plane as the upper end 71b of the memory film 71. The upper end 75b of the second cap portion 75 is in contact with the lower surface 54a of the upper contact 54. Therefore, the second cap portion 75 and the upper contact 54 are electrically connected. The second cap portion 75 does not protrude into the upper contact 54.

### 4.7 Bit Line

Next, the bit line BL will be described. The bit line BL is an interconnection whose voltage is controlled to select the memory pillar 55. The plurality of bit lines BL are disposed to be aligned in the X direction. Each of the bit lines BL extends in the Y direction. Each bit line BL is disposed on a side opposite to the source line SL with respect to the memory pillar 55. The bit line BL is disposed above the upper contact 54. The bit line BL is, for example, a copper interconnection that is an interconnection containing copper.

The contact 56 extending in the Z direction is provided between the bit line BL and the upper contact 54. The bit line BL is electrically connected to the upper end 55b of the memory pillar 55 via the contact 56 and the upper contact 54. For example, the bit line BL is electrically connected to the second cap portion 75 of the memory pillar 55 via the contact 56 and the upper contact 54. Therefore, a memory cell transistor MT can be optionally selected from among the plurality of memory cell transistors MT disposed three-dimensionally by a combination of the word line WL and the bit line BL.

### 4.8 Staircase Portion

Next, returning to FIG. 3, a staircase portion 80 provided in the memory cell array 11 will be described.

The staircase portion 80 is a structure configured to secure electrical connection to the plurality of conductive layers 61. In the staircase portion 80, the plurality of conductive layers 61, for example, have longer lengths in the X direction as the conductive layers 61 are positioned further downward. Therefore, an end part of each conductive layer 61 in the X direction has a terrace portion that does not overlap other conductive layers 61 positioned above the conductive layer 61. The staircase portion 80 is covered with the third insulating portion 43.

In the present embodiment, the plurality of conductive layers 61 include a first conductive layer 61A, a second conductive layer 61B, and a third conductive layer 61C. The first conductive layer 61A is positioned uppermost among the three conductive layers 61A, 61B, and 61C. The second conductive layer 61B is positioned at a center among the three conductive layers 61A, 61B, and 61C. In other words, the second conductive layer 61B is disposed between the first conductive layer 61A and the semiconductor substrate 21. The third conductive layer 61C is positioned lowermost among the three conductive layers 61A, 61B, and 61C. In other words, the third conductive layer 61C is disposed between the second conductive layer 61B and the semiconductor substrate 21. The first conductive layer 61A is an example of a “first gate electrode layer”. The second conductive layer 61B is an example of a “second gate electrode layer”. The third conductive layer 61C is an example of a “third gate electrode layer”. In the present embodiment, a length of the second conductive layer 61B in the X direction is larger than a length of the first conductive layer 61A in the X direction. A length of the third conductive layer 61C in the X direction is larger than a length of the second conductive layer 61B in the X direction.

The plurality of contacts 81 are disposed on an upper side of the staircase portion 80. The plurality of contacts 81 have conductivity and extend in the Z direction. The contacts 81 are each an electrical connection portion that connects the conductive layer 61 and an interconnection 101 included in the upper layer interconnection portion 100. The plurality of contacts 81 are disposed at positions corresponding to the terrace portions of the plurality of conductive layers 61 when viewed from above. The plurality of contacts 81 have different lengths in the Z direction. A lower end of each contact 81 is in contact with the terrace portion of the corresponding conductive layer 61.

For example, the plurality of contacts 81 include a first contact 81A, a second contact 81B, and a third contact 81C. The first contact 81A is provided corresponding to a terrace portion of the first conductive layer 61A and is in contact with the terrace portion of the first conductive layer 61A. The second contact 81B extends further downward than the first contact 81A. The second contact 81B is provided corresponding to a terrace portion of the second conductive layer 61B and is in contact with the terrace portion of the second conductive layer 61B. The third contact 81C extends further downward than the second contact 81B. The third contact 81C is provided corresponding to a terrace portion of the third conductive layer 61C and is in contact with the terrace portion of the third conductive layer 61C.

### 4.9 Dividing Portion

Next, the dividing portion ST will be described.

FIG. 7 is a cross-sectional view along line F7-F7 of the memory cell array 11 shown in FIG. 3. The dividing portion ST extends in the Z direction and penetrates the multi-layered body 51 and the insulating layer 52. The dividing portion ST is a wall portion that divides the multi-layered body 51 in the Y direction.

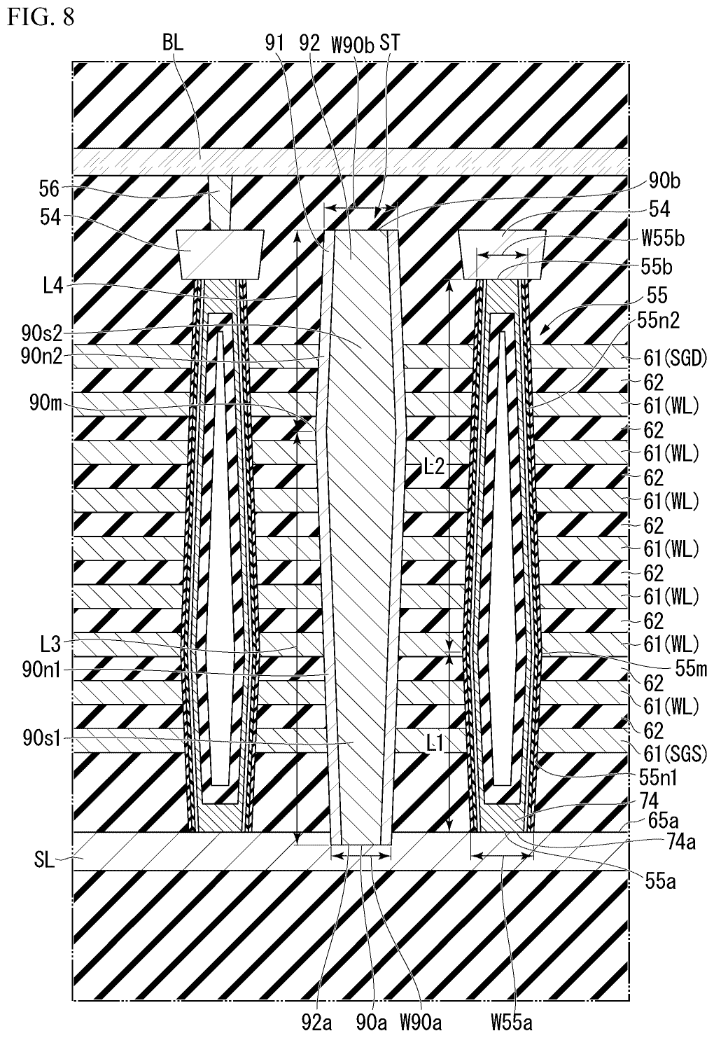

FIG. 8 is a cross-sectional view showing a region surrounded by line F8 of the memory cell array 11 shown in FIG. 7. The dividing portion ST includes, for example, an insulating portion 91 and a conductive portion 92.

The insulating portion 91 forms an outer shell of the dividing portion ST. The insulating portion 91 extends in the Z direction and penetrates the multi-layered body 51 and the insulating layer 52. The insulating portion 91 divides each of the plurality of conductive layers 61 included in the multi-layered body 51 in the Y direction. The insulating portion 91 is formed of an insulating material such as silicon oxide.

The conductive portion 92 is provided inside the insulating portion 91. The conductive portion 92 extends in the Z direction and penetrates the multi-layered body 51 and the insulating layer 52. A lower end 92a of the conductive portion 92 is positioned inside the source line SL. The conductive portion 92 is formed of a conductive material such as tungsten or polysilicon. The conductive portion 92 is an interconnection that connects the source line SL and an interconnection in the memory cell array 11.

The dividing portion ST has a lower end 90a and an upper end 90b. The lower end 90a is in contact with the source line SL. The upper end 90b is positioned on a side opposite to the lower end 90a in the Z direction. In the present embodiment, a width W90a of the lower end 90a in the Y direction is smaller than a width W90b of the upper end 90b in the Y direction. The lower end 90a is an example of a “third end”. The upper end 90b is an example of a “fourth end”. Here, the width W90a of the lower end 90a may be defined as, for example, a width in the Y direction of a portion 90s1 of the dividing portion ST that faces the lowermost conductive layer 61 among the plurality of conductive layers 61. Also, the width W90b of the upper end 90b may be defined as, for example, a width in the X direction of a portion 90s2, that faces the uppermost conductive layer 61 among the plurality of conductive layers 61, in the dividing portion ST. Therefore, “the width W90a in the Y direction of the lower end 90a of the dividing portion ST is larger than the width W90b in the X direction of the upper end 90b of the dividing portion ST” means, for example, that a width in the Y direction of the portion 90s1 of the dividing portion ST is larger than a width in the X direction of the portion 90s2 of the dividing portion ST.

In the present embodiment, the dividing portion ST has a maximum width portion 90m, a first portion 90n1, and a second portion 90n2. The maximum width portion 90m is a portion of the dividing portion ST that has a maximum width in the Y direction. In the present embodiment, the maximum width portion 90m is positioned above a center of the dividing portion ST in the Z direction.

The first portion 90n1 is a tapered portion positioned between the lower end 90a and the maximum width portion 90m, and in which a width of the dividing portion ST in the Y direction decreases downward. The second portion 90n2 is an expanding portion positioned between the upper end 90b and the maximum width portion 90m, and in which a width of the dividing portion ST in the Y direction increases downward. In the present embodiment, a length L4 in the Z direction of the second portion 90n2 is smaller than a length L3 in the Z direction of the first portion 90n1.

### 4.10 Upper Dividing Portion

Next, returning to FIG. 7, the upper dividing portion SHE will be described. The upper dividing portion SHE is a dividing portion shallower than the dividing portion ST. The upper dividing portion SHE is provided at an upper end part of the multi-layered body 51 and extends to a middle of the multi-layered body 51 in the Z direction. The upper dividing portion SHE extends in the X direction. The upper dividing portion SHE penetrates the conductive layer 61 functioning as the drain-side selection gate line SGD. On the other hand, the upper dividing portion SHE does not reach the conductive layer 61 functioning as the word line WL. The upper dividing portion SHE is a wall portion that divides the conductive layers 61 functioning as the drain-side selection gate line SGD in the Y direction. The upper dividing portion SHE is formed of an insulating material such as silicon oxide. In the present embodiment, a region partitioned by the upper dividing portions SHE corresponds to one string unit SU. The conductive layer 61 corresponding to the drain-side selection gate line SGD is divided in the Y direction by the dividing portion ST and the upper dividing portion SHE. Therefore, the drain-side selection gate line SGD extending in the X direction is formed.

### 5. Upper Layer Interconnection Portion

Next, the upper layer interconnection portion 100 will be described. The upper layer interconnection portion 100 is provided above the multi-layered body 51. The upper layer interconnection portion 100 includes a plurality of interconnections 101. The plurality of interconnections 101 include, for example, a first interconnection 101A (refer to FIG. 3) electrically connected to the contact 81 for the staircase portion 80, a second interconnection 101B (refer to FIG. 7) electrically connected to the bit line BL, and a third interconnection 101C (refer to FIG. 7) electrically connected to the pad 44. Each of the plurality of interconnections 101 is, for example, a copper interconnection that is an interconnection containing copper. In the present embodiment, the plurality of copper interconnections (for example, the plurality of interconnections 101) are disposed above the second cap portion 75 of the memory pillar 55 in the semiconductor storage device 1. In the present embodiment, no copper interconnection is present below the second cap portion 75. The upper layer interconnection portion 100 is an example of a “connection interconnection portion”.

### 6. Electrical Connection Portion Including Through Contact

Next, the electrical connection portion 110 will be described. The electrical connection portion 110 is an electrical connection portion that electrically connects the first chip 2 and the second chip 3. For example, the electrical connection portion 110 is an electrical connection portion that electrically connects the peripheral circuit 22 of the first chip 2 and the plurality of interconnections 101 included in the upper layer interconnection portion 100 of the second chip 3. The electrical connection portion 110 includes, for example, a first electrical connection portion 111, a second electrical connection portion 112, and a third electrical connection portion 113.

The first electrical connection portion 111 is a connection portion that electrically connects the transistor 31 included in the peripheral circuit 22 and the first interconnections 101A included in the upper layer interconnection portion 100. That is, the first electrical connection portion 111 electrically connects the transistor 31 included in the peripheral circuit 22 to the conductive layer 61. The first electrical connection portion 111 includes a first through contact 121. The first through contact 121 has conductivity and extends in the Z direction.

The first through contact 121 penetrates the second insulating portion 42 of the second chip 3 and at least a part of the first insulating portion 23 of the first chip 2. The first through contact 121 extends in the Z direction from below the source line SL to above the upper end 55b of the memory pillar 55 and electrically connects the transistor 31 of the peripheral circuit 22 to the conductive layer 61. For example, the first through contact 121 is connected to the interconnection 33a included in the interconnection layer 33 inside the first chip 2. The first through contact 121 is connected to the first interconnection 101A included in the upper layer interconnection portion 100 inside the second chip 3 (for example, at a position above the upper end 55b of the memory pillar 55).

The second electrical connection portion 112 is a connection portion that electrically connects another transistor 31 included in the peripheral circuit 22 and the second interconnection 101B included in the upper layer interconnection portion 100. That is, the second electrical connection portion 112 electrically connects the transistor 31 included in the peripheral circuit 22 and the bit line BL. The second electrical connection portion 112 includes a second through contact 122. The second through contact 122 has conductivity and extends in the Z direction.

The second through contact 122 penetrates the second insulating portion 42 of the second chip 3 and at least a part of the first insulating portion 23 of the first chip 2. The second through contact 122 extends in the Z direction from below the source line SL to above the upper end 55b of the memory pillar 55, and electrically connects the transistor 31 of the peripheral circuit 22 to the bit line BL. The second through contact 122 is connected to the interconnection 33a included in the interconnection layer 33 inside the first chip 2. The second through contact 122 is connected to the interconnections 101B included in the upper layer interconnection portion 100 inside the second chip 3 (for example, at a position above the upper end 55b of the memory pillar 55).

The third electrical connection portion 113 is a connection portion that electrically connects another transistor 31 included in the peripheral circuit 22 and the third interconnection 101C included in the upper layer interconnection portion 100. That is, the third electrical connection portion 113 connects the transistor 31 included in the peripheral circuit 22 and the pad 44. The third electrical connection portion 113 includes a third through contact 123. The third through contact 123 has conductivity and extends in the Z direction.

The third through contact 123 penetrates the second insulating portion 42 of the second chip 3 and at least a part of the first insulating portion 23 of the first chip 2 in the Z direction. The third through contact 123 is connected to the interconnection 33a included in the interconnection layer 33 inside the first chip 2. The third through contact 123 is connected to the interconnection 101C included in the upper layer interconnection portion 100 inside the second chip 3 (for example, at a position above the upper end 55b of the memory pillar 55).

### 7. Other Configurations

As shown in FIGS. 3 and 7, in the present embodiment, there is no copper pad for bonding the first chip 2 and the second chip 3 together. In other words, there is no copper pad between the source line SL and the semiconductor substrate 21.

### 8. Manufacturing Method

Next, a method of manufacturing the semiconductor storage device 1 will be described.

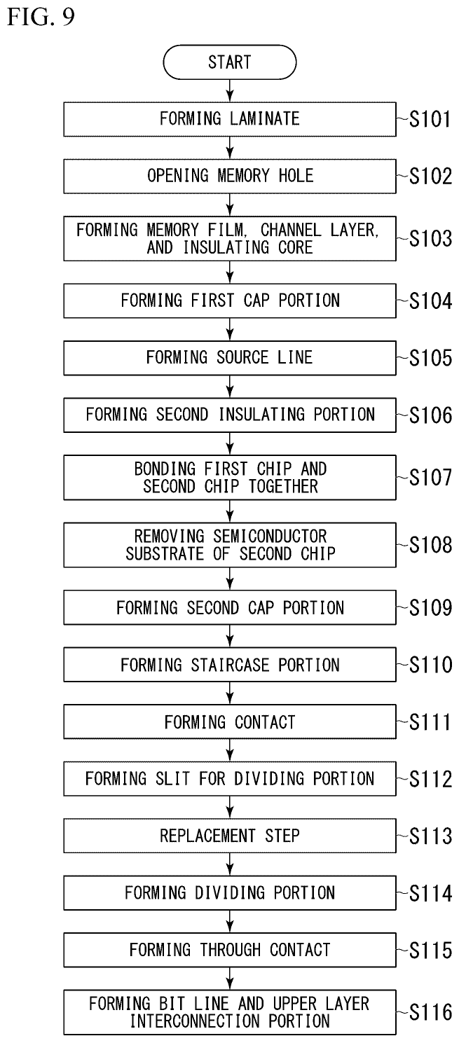

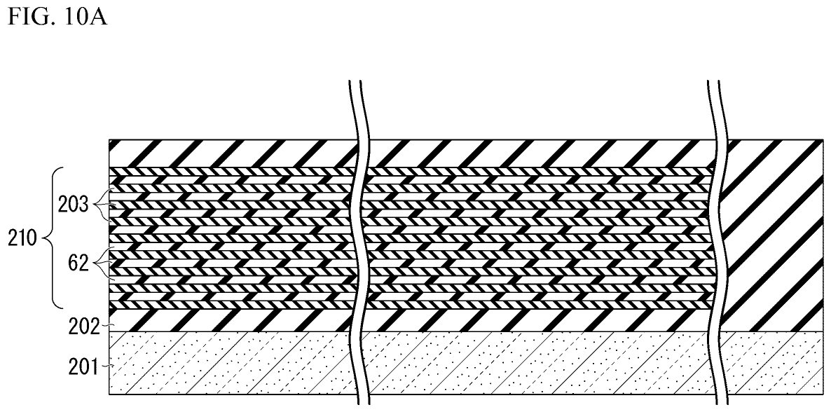

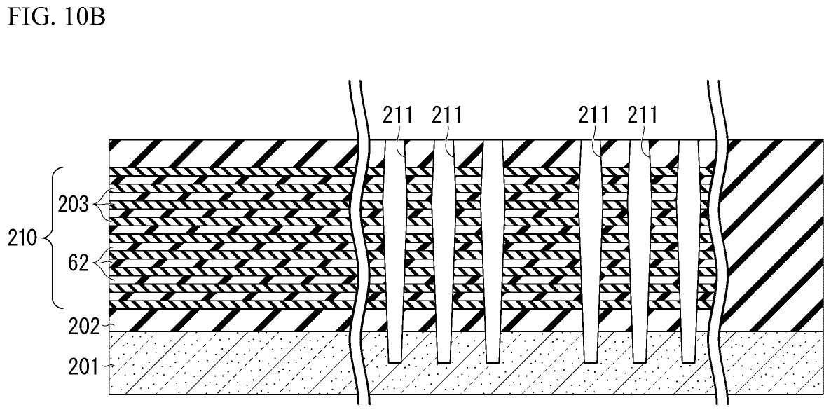

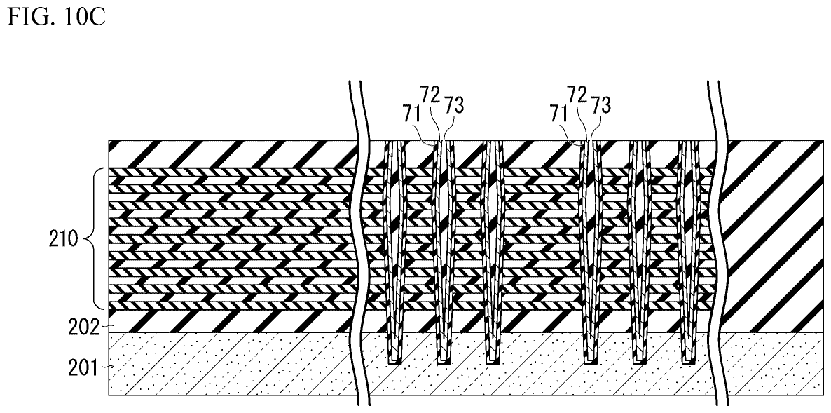

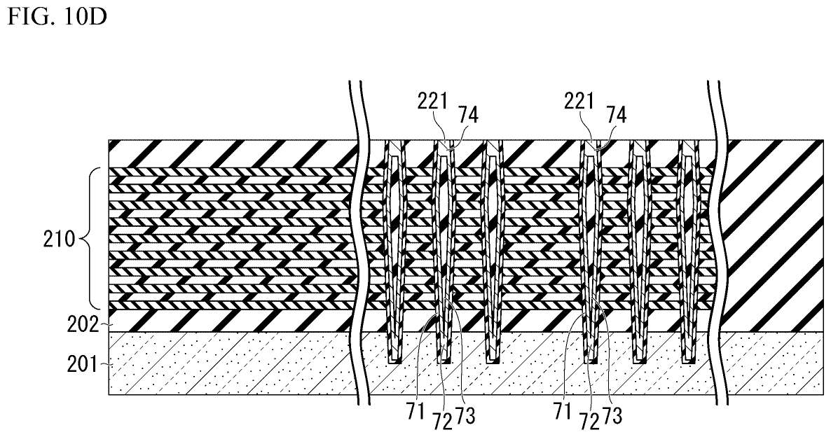

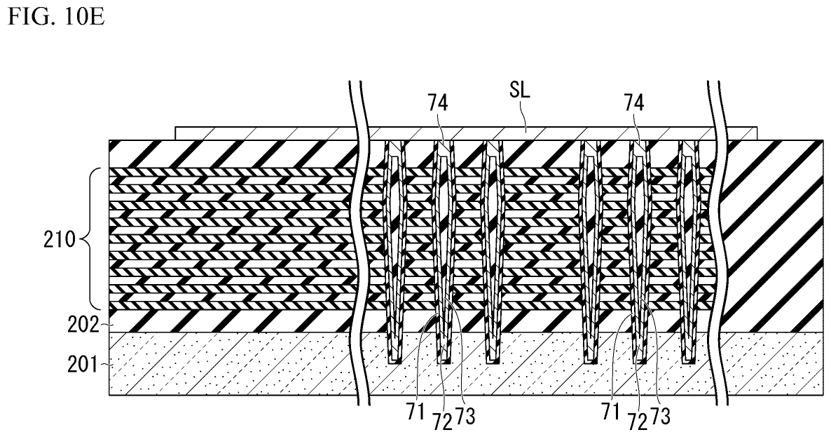

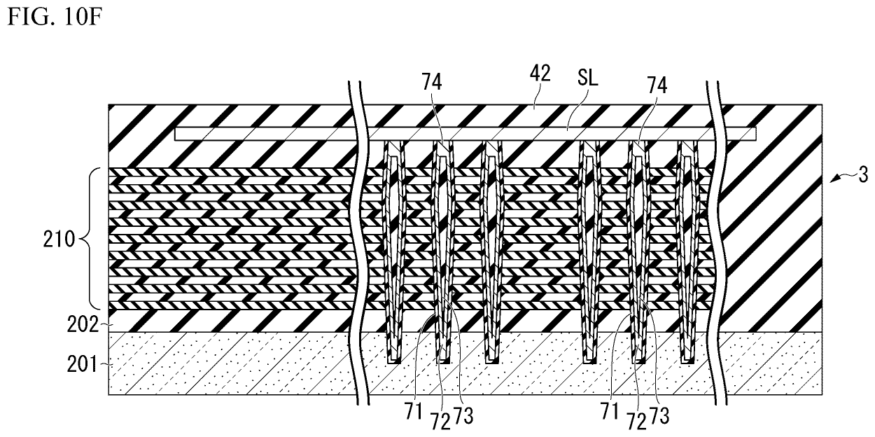

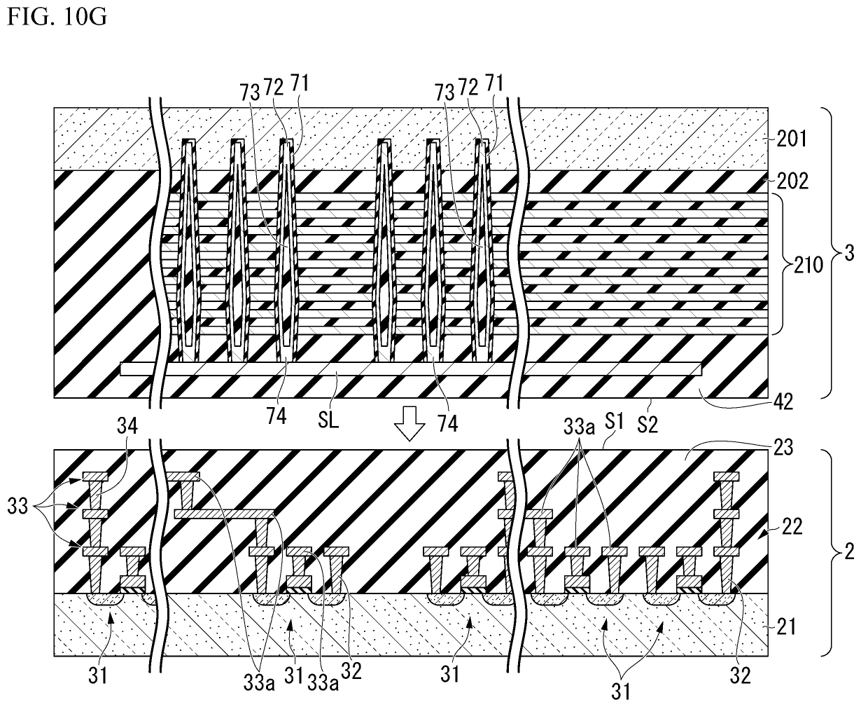

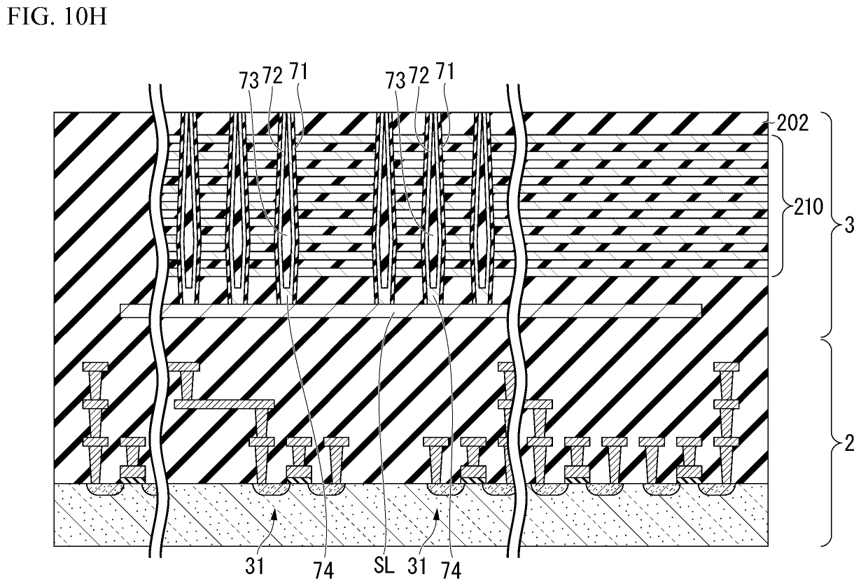

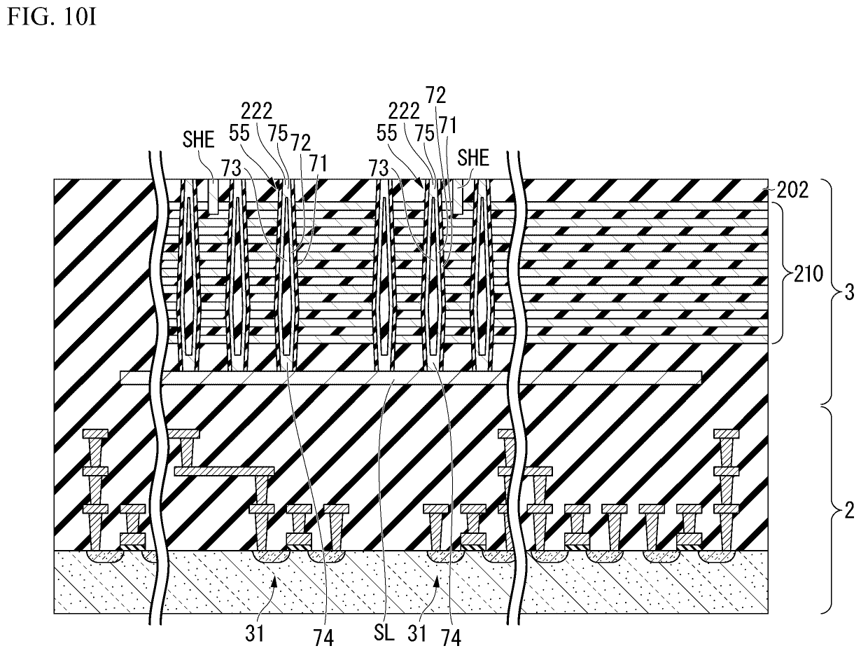

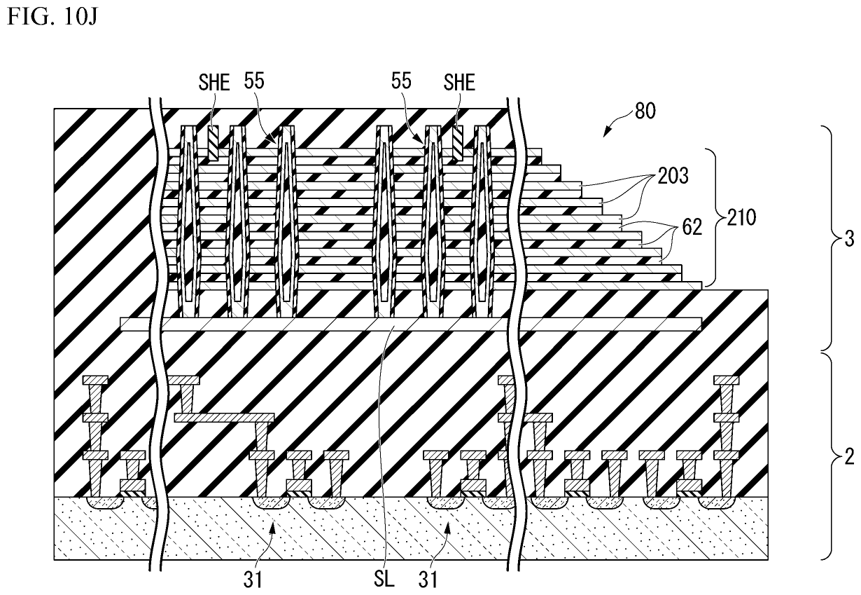

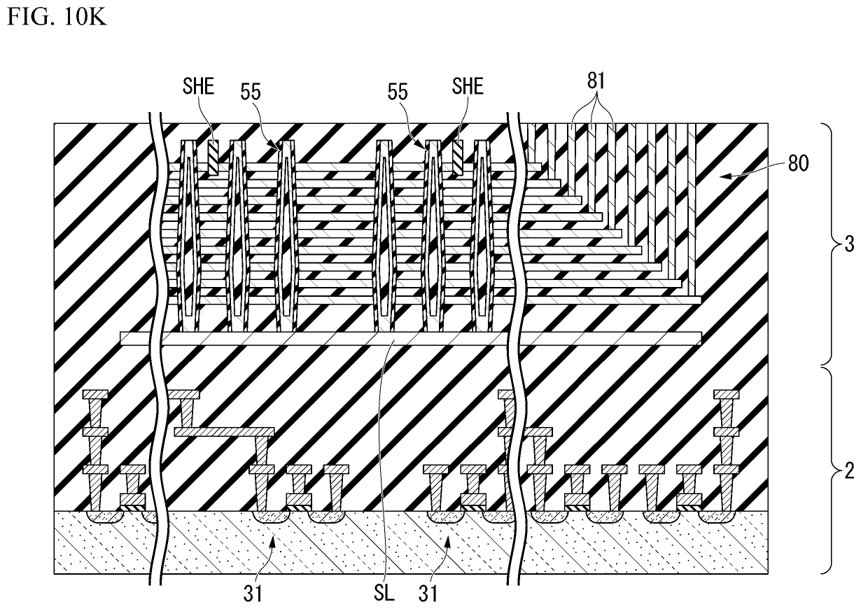

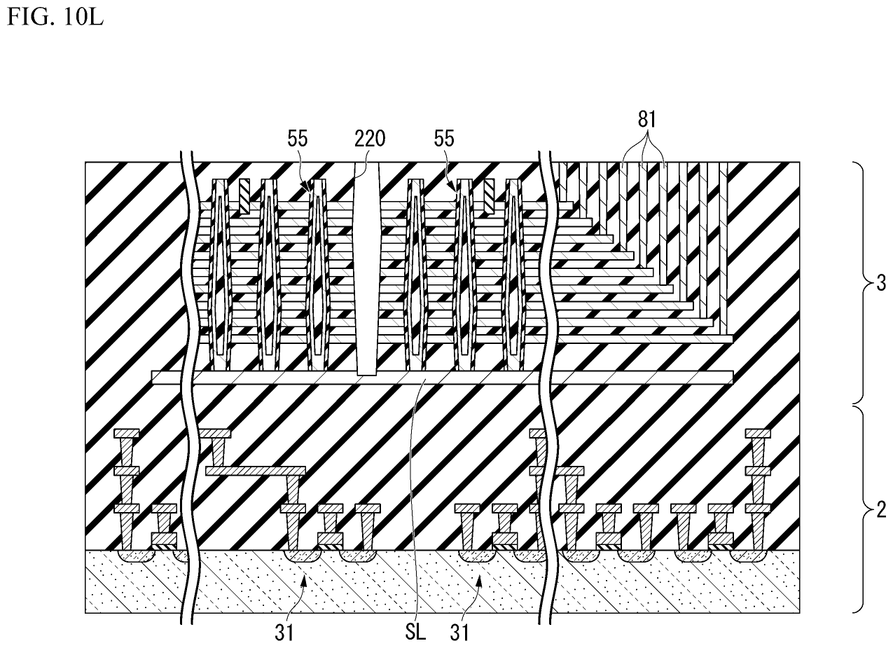

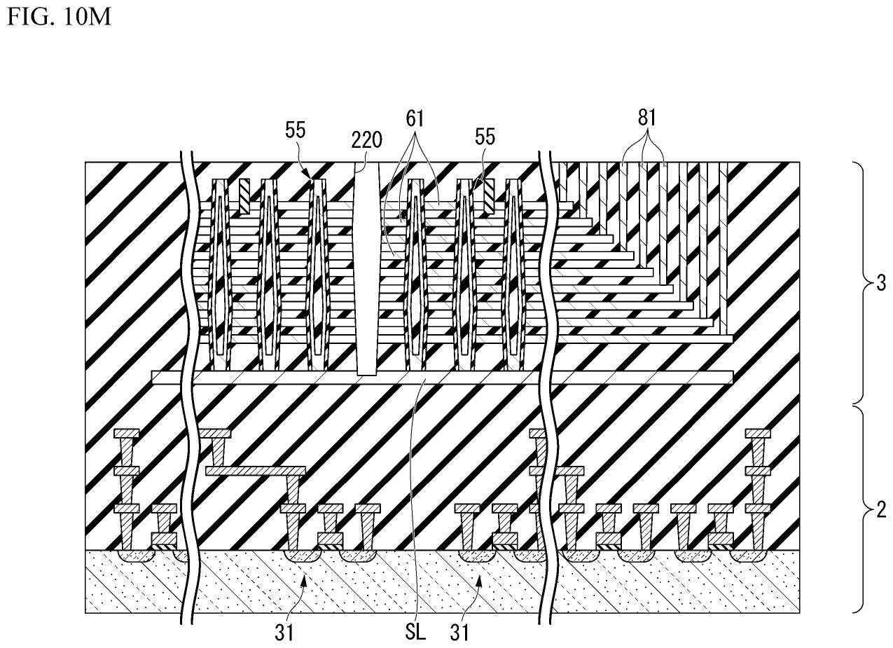

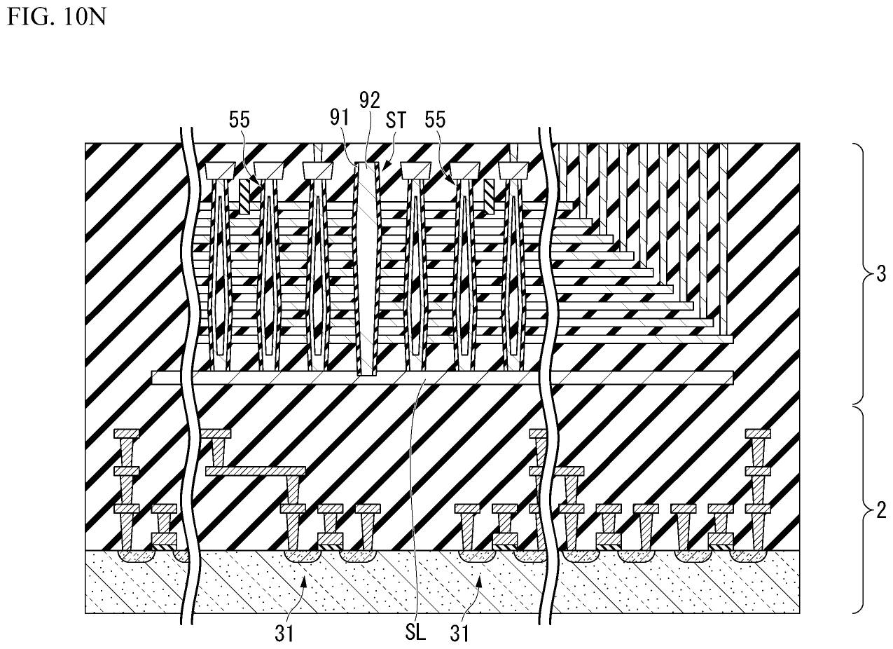

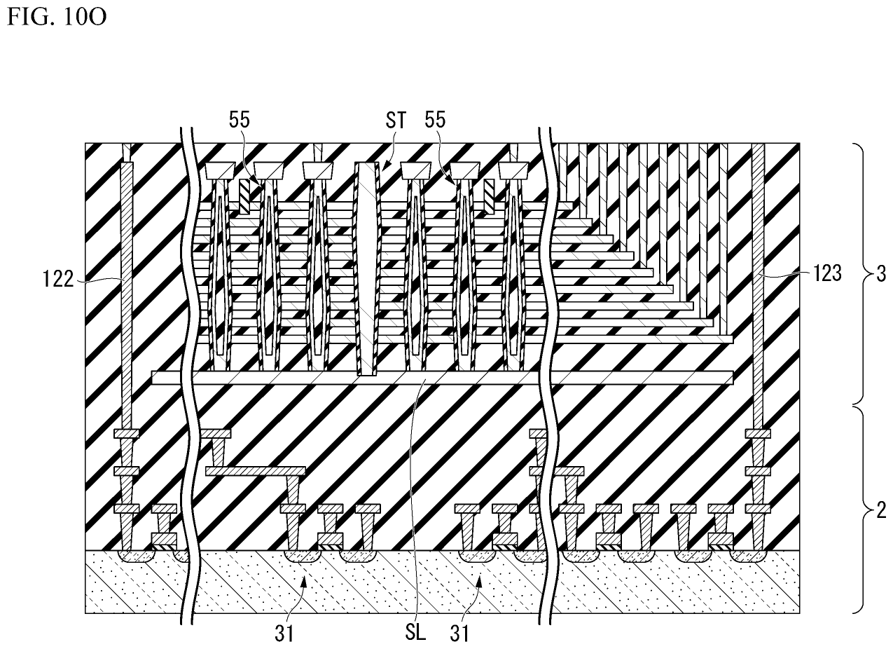

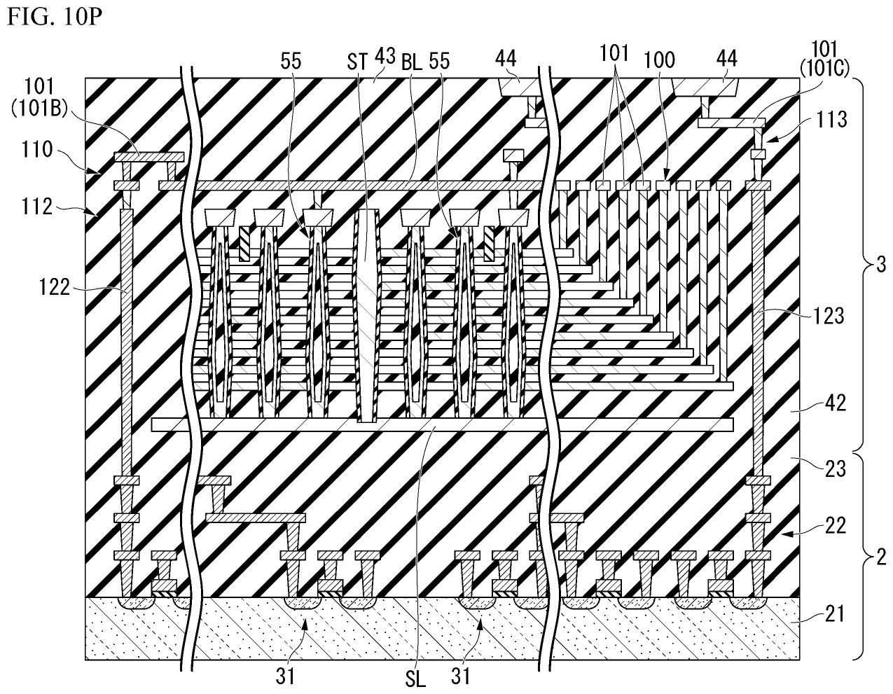

FIG. 9 is a diagram showing a flow of a method of manufacturing the semiconductor storage device 1. FIGS. 10A to 10P are views for explaining a method of manufacturing the semiconductor storage device 1.

First, an insulating layer 202 is formed on the semiconductor substrate 201. Next, sacrificial layers 203 and the insulating layers 62 are alternately stacked on the insulating layer 202 to form a multi-layered body 210 (S101 in FIG. 9, see FIG. 10A). The sacrificial layer 203 is formed of, for example, silicon nitride. The sacrificial layer 203 is an example of a “first layer”. The insulating layer 62 is an example of a “second layer”.

Next, a memory hole 211 serving as a hole for forming the memory pillar 55, is formed in the multi-layered body 210 (S102 in FIG. 9, see FIG. 10B). Next, inside the memory hole 211, the memory film 71, the channel layer 72, and the insulating core 73 are formed in that order (S103 in FIG. 9, see FIG. 10C).

Next, the first cap portion 74 is formed (S104 in FIG. 9, see FIG. 10D). For example, an end part of the insulating core 73 positioned at a first end part 221 of the memory pillar 55 is removed by etching. Next, a silicon material is supplied into a recess generated by removing the end part of the insulating core 73, and thereby the recess is filled therewith. Next, the silicon material supplied to the recess is doped with impurities (for example, phosphorus) and heat-treated to diffuse the impurities and crystallize the silicon material. Therefore, the first cap portion 74 is formed on the first end part 221 of the memory pillar 55.

Next, the source line SL is formed on the first cap portion 74 (S105 in FIG. 9, see FIG. 10E). For example, the source line SL is formed by supplying a tungsten or silicon material on the multi-layered body 210 and the first cap portion 74 and performing necessary processing. Next, an insulating material is supplied to cover the source line SL to form the second insulating portion 42 covering the source line SL (S106 in FIG. 9, see FIG. 10F). Therefore, the second chip 3 is formed.

Next, the first chip 2 prepared separately and the second chip 3 formed in the above-described processes are bonded together (S107 in FIG. 9, see FIG. 10G). For example, the second chip 3 is vertically inverted, the first surface S1 of the first insulating portion 23 of the first chip 2 and the second surface S2 of the second insulating portion 42 of the second chip 3 are overlapped, and then heated to a predetermined temperature and pressurized. Therefore, the first chip 2 and the second chip 3 are bonded together.

Next, a back surface of the second chip 3 is polished by chemical mechanical polishing (CMP) or the like, and the semiconductor substrate 201 of the second chip 3 is removed (S108 in FIG. 9, see FIG. 10H). Next, the second cap portion 75 is formed (S109 in FIG. 9, see FIG. 10I). For example, the end part of the insulating core 73 positioned at a second end part 222 of the memory pillar 55 is removed by etching. Next, a silicon material is supplied into the recess generated by removing the end part of the insulating core 73, and thereby the recess is filled therewith. Next, the silicon material supplied to the recess is doped with impurities (for example, phosphorus) and heat-treated to diffuse the impurities and crystallize the silicon material. Therefore, the second cap portion 75 is formed. Next, the upper dividing portion SHE is formed with respect to the multi-layered body 210.

Next, the staircase portion 80 is formed at an end part of the multi-layered body 210 by a method such as slimming (S110 in FIG. 9, FIG. 10J). Next, an insulating portion covering the staircase portion 80 is provided, and the plurality of contacts 81 are formed for the staircase portion 80 (S111 in FIG. 9, see FIG. 10K).

Next, a slit 220 for forming the dividing portion ST is formed in the multi-layered body 210 (S112 in FIG. 9, see FIG. 10L). Next, a replacement step of replacing a plurality of sacrificial layers 203 with the plurality of conductive layers 61 is performed (S113 in FIG. 9, see FIG. 10M). For example, the sacrificial films 203 of the multi-layered body 210 are each removed by supplying hot phosphoric acid or the like through the slit 220, and a conductive material is supplied into the removed space. Therefore, the multi-layered body 51 including the plurality of conductive layers 61 is formed. Thereafter, the dividing portion ST is provided inside the slit 220, and an insulating portion is provided on the multi-layered body 51 (refer to S114 in FIG. 9, see FIG. 10N).

Next, an electrical connection portion 120 including the through contacts 121, 122, and 123 is provided (S115 in FIG. 9, see FIG. 10O). Finally, the bit line BL, the interconnection 101 included in the upper layer interconnection portion 100, and the pad 44 are formed (S116 in FIG. 9, see FIG. 10P). Therefore, the semiconductor storage device 1 is manufactured.

### 9. Advantages

As comparative example 1, an example in which the multi-layered body 51 including the conductive layer 61 (word line WL) and the insulating layer 62 is formed above the peripheral circuit 22 provided on the semiconductor substrate 21 will be considered. In this comparative example, the source line SL is formed between the multi-layered body 51 and the semiconductor substrate 21. In this case, a structure of a connection portion between the source line SL and the memory pillar 55 may become complicated. For example, in recent highly stacked semiconductor storage devices, a process of forming a connection portion between a lower end part of the memory pillar 55 positioned at a lower end part of the multi-layered body 51 and the source line SL has become complicated. As a result, manufacturability of the semiconductor storage device may be decreased.

As comparative example 2, an example in which the second chip 3 including the memory cell array 11 is formed separately from the first chip 2 including the peripheral circuit 22, and the first chip 2 and the second chip 3 are bonded together using a copper pad for bonding to form the semiconductor storage device will be considered. In this case, after the first chip 2 and the second chip 3 are bonded together, it is necessary to consider copper diffusion from the copper pad, making it difficult to perform a heat treatment at a high temperature. Therefore, in the process of forming the source line SL on the upper end part of the second chip 3 after it is bonded to the first chip 2, it is difficult to perform a heat treatment for crystallizing polysilicon and diffusing impurities, complicating the process of forming the connection portion between the memory pillar 55 and the source line SL. As a result, manufacturability of the semiconductor storage device may be decreased.

On the other hand, the semiconductor storage device 1 of the present embodiment includes the semiconductor substrate 21, the transistor 31, the multi-layered body 51, the memory pillar 55, and the source line SL. The transistor 31 is provided on the semiconductor substrate 21. The multi-layered body 51 is disposed on a side opposite to the semiconductor substrate 21 with respect to the transistor 31. The memory pillar 55 extends in the Z direction within the multi-layered body 51. The source line SL is disposed between the multi-layered body 51 and the semiconductor substrate 21. The memory pillar 55 has the lower end 55a in contact with the source line SL, and the upper end 55b positioned on a side opposite to the lower end 55a. The width W55a of the lower end 55a in the X direction is larger than the width W55b of the upper end 55b in the X direction.

According to such a configuration, the source line SL can be formed in a state in which the source line SL is positioned above the multi-layered body 210. Therefore, even when the multi-layered body 210 is highly stacked, the connection portion between the memory pillar 55 and the source line SL can be easily formed compared to, for example, that of comparative example 1 or comparative example 2. Therefore, it is possible to improve manufacturability of the semiconductor storage device 1.

In the present embodiment, the memory pillar 55 has the first cap portion 74 disposed at least between the insulating core 73 and the source line SL and containing polysilicon. According to such a configuration, it is possible to further improve connectivity and conductivity between the first cap portion 74 and the source line SL. Therefore, it is possible to improve electrical characteristics of the semiconductor storage device 1.

In the present embodiment, there is no copper pad between the source line SL and the semiconductor substrate 21. According to such a configuration, there is less need to consider copper diffusion, and a heat treatment can be performed at a high temperature during formation of the source line SL or the first cap portion 74 compared to a case in which a copper pad is present between the source line SL and the semiconductor substrate 21 as in comparative example 2 described above. Therefore, it is possible to improve electrical characteristics of the semiconductor storage device 1.

In the present embodiment, the memory pillar 55 includes the second cap portion 75 disposed at least between the insulating core 73 and the bit line BL and containing polysilicon. The upper layer interconnection portion 100 includes a plurality of copper interconnections (for example, the plurality of interconnections 101). The plurality of copper interconnections are disposed above the second cap portion 75 in the semiconductor storage device 1, and no copper interconnection is present below the second cap portion 75. According to such a configuration, there is less need to consider copper diffusion compared to a case in which the copper interconnection is present below the second cap portion 75, and a heat treatment can be performed at a high temperature during formation of the second cap portion 75. Therefore, it is possible to improve electrical characteristics of the semiconductor storage device 1.

In the present embodiment, the semiconductor storage device 1 further includes the dividing portion ST penetrating the multi-layered body 51 in the Z direction and dividing each of the plurality of conductive layers 61 in the Y direction. The dividing portion ST has the lower end 90a in contact with the source line SL, and the upper end 90b positioned on a side opposite to the lower end 90a. The width W90a of the lower end 90a in the Y direction is smaller than the width W90b of the upper end 90b in the Y direction. That is, when viewed macroscopically, the dividing portion ST is larger on the upper side and smaller on the lower side. On the other hand, when viewed macroscopically, the memory pillar 55 is smaller on the upper side and larger on the lower side. According to such a configuration, the maximum diameter portion 55m of the memory pillar 55 and the maximum width portion 90m of the dividing portion ST from being adjacent to each other in the X or Y direction can be avoided. Therefore, a distance between the memory pillar 55 and the dividing portion ST can be reduced, and a size of the semiconductor storage device 1 can be made smaller.

### Second Embodiment

Next, a second embodiment will be described. The second embodiment is different from the first embodiment in that a lower end part of a memory pillar 55 does not have a first cap portion 74. Note that, configurations other than those described below are the same as the configurations of the first embodiment.

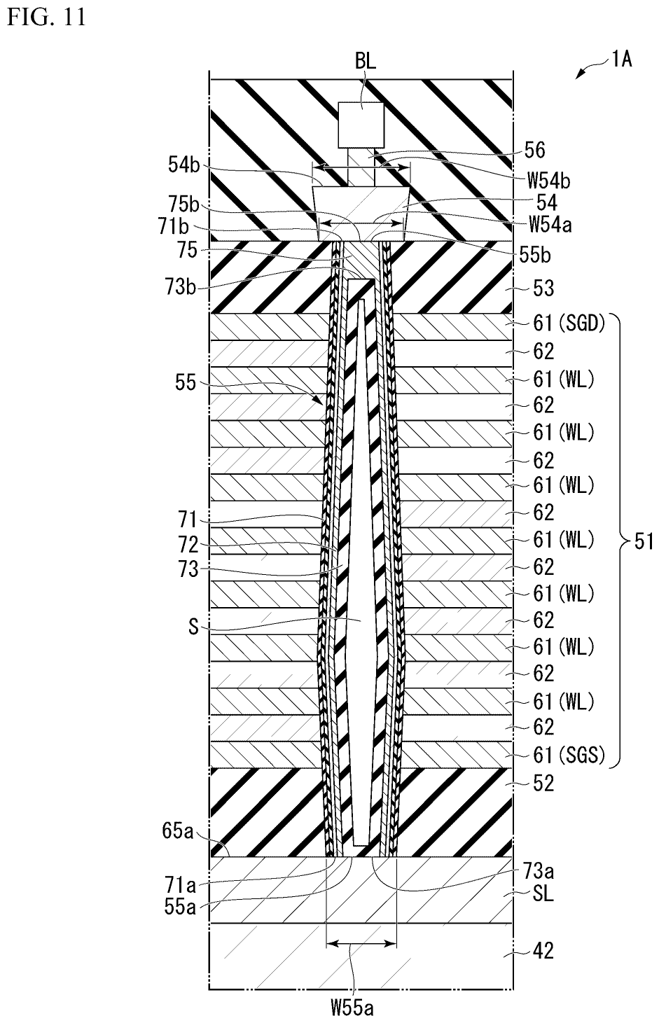

FIG. 11 is a cross-sectional view showing a part of a semiconductor storage device 1A according to the second embodiment. In the present embodiment, the lower end part of the memory pillar 55 does not have the first cap portion 74. At the lower end part of the memory pillar 55, a memory film 71, a channel layer 72, and an insulating core 73 each extend in the Z direction, and each of the memory film 71, the channel layer 72, and the insulating core 73 is in contact with an upper surface 65a of a source line SL. In the present embodiment, a lower end 71a of the memory film 71 and a lower end 73a of the insulating core 73 are positioned on the same plane. However, the memory film 71, the channel layer 72, and the insulating core 73 do not protrude below the upper surface 65a of the source line SL (that is, to the side of the semiconductor substrate 21).

According to such a configuration, as in the first embodiment, the source line SL can be formed in a state in which the source line SL is positioned above a multi-layered body 210. Therefore, manufacturability of the semiconductor storage device 1A can be improved.

### Third Embodiment

Next, a third embodiment will be described. The third embodiment is different from the first embodiment in that the memory pillar 55 is a pillar having a two-stage configuration including a lower pillar 231 and an upper pillar 232. Note that, configurations other than those described below are the same as the configurations of the first embodiment. Note that, the present embodiment describes a pillar with a two-stage configuration, but the pillar may have a configuration with three or more stages.

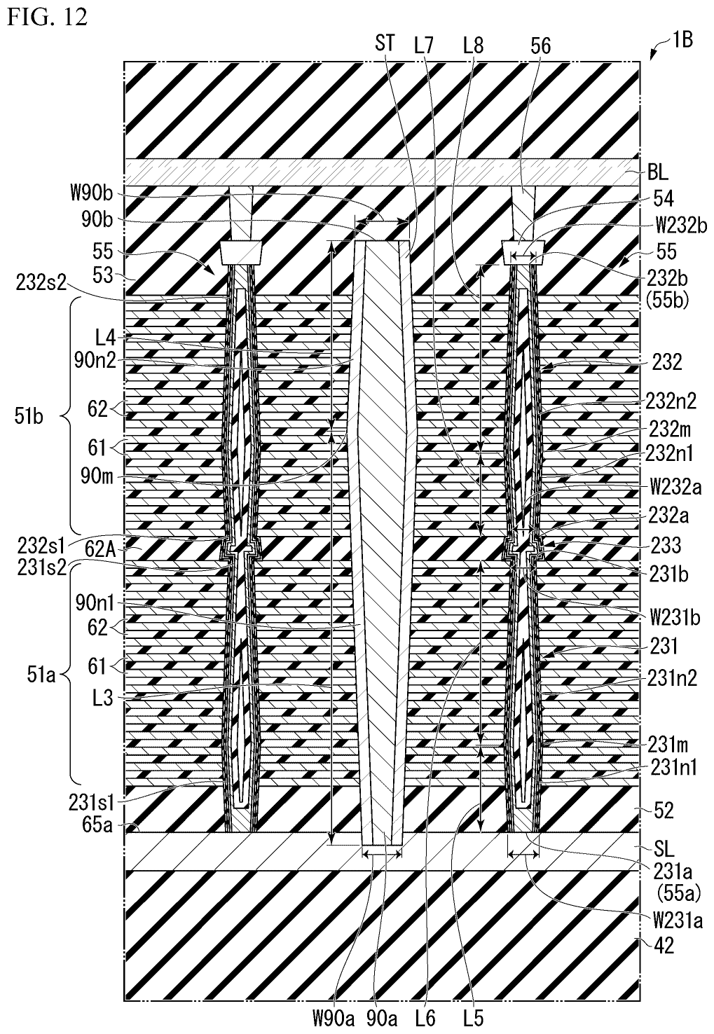

FIG. 12 is a cross-sectional view showing a part of a semiconductor storage device 1B of the third embodiment. In the present embodiment, a multi-layered body 51 includes a lower multi-layered body (first multi-layered body) 51a, an upper multi-layered body (second multi-layered body) 51b, and an insulating layer 62A. In the lower multi-layered body 51a, a plurality of conductive layers 61 and a plurality of insulating layers 62 are alternately stacked one by one in the Z direction. The upper multi-layered body 51b is disposed above the lower multi-layered body 51a. In the upper multi-layered body 51b, the plurality of conductive layers 61 and the plurality of insulating layers 62 are alternately stacked one by one in the Z direction. The insulating layer 62A is disposed between the lower multi-layered body 51a and the upper multi-layered body 51b. A thickness in the Z direction of the insulating layer 62A is larger than a thickness in the Z direction of the insulating layer 62 included in the lower multi-layered body 51a, and is larger than a thickness in the Z direction of the insulating layer 62 included in the upper multi-layered body 51b.

The memory pillar 55 includes the lower pillar 231, the upper pillar 232, and a connection portion 233.

The lower pillar 231 extends in the Z direction within the lower multi-layered body 51a. The lower pillar 231 has a lower end 231a and an upper end 231b. The lower end 231a is a lower end 55a of the memory pillar 55. The lower end 231a is in contact with a source line SL. The upper end 231b is positioned on a side opposite to the lower end 231a in the Z direction. The upper end 231b is in contact with a connection portion 233 to be described later. In the present embodiment, a width W231a of the lower end 231a in the X direction is larger than a width W231b of the upper end 231b in the X direction. Here, the width W231a of the lower end 231a may be defined as, for example, a width in the X direction of a portion 231s1 of the lower pillar 231 that faces a lowermost conductive layer 61 among the plurality of conductive layers 61 of the lower multi-layered body 51a. Also, the width W231b of the upper end 231b may be defined as, for example, a width in the X direction of a portion 231s2 of the lower pillar 231 that faces an uppermost conductive layer 61 among the plurality of conductive layers 61 of the lower multi-layered body 51a. Therefore, “the width W231a in the X direction of the lower end 231a of the lower pillar 231 is larger than the width W231b in the X direction of the upper end 231b of the lower pillar 231” means, for example, that a width in the X direction of the portion 231s1 of the lower pillar 231 is larger than a width in the X direction of the portion 231s2 of the lower pillar 231.

The lower pillar 231 has a maximum outer diameter portion (maximum width portion) 231m, a first portion 231n1, and a second portion 231n2. The maximum outer diameter portion 231m is a portion whose outer diameter (that is, a width in the X direction or Y direction) is the largest in the lower pillar 231. In the present embodiment, the maximum outer diameter portion 231m is positioned below a center of the lower pillar 231 in the Z direction.

The first portion 231n1 is a diameter reducing portion positioned between the lower end 231a and the maximum outer diameter portion 231m, and in which an outer diameter of the memory pillar 55 reduces downward. The second portion 231n2 is a diameter expanding portion positioned between the upper end 231b and the maximum outer diameter portion 231m, and in which an outer diameter of the memory pillar 55 increases downward. A length L6 in the Z direction of the second portion 231n2 is larger than a length L5 in the Z direction of the first portion 231n1.

The upper pillar 232 extends in the Z direction within the upper multi-layered body 51b. The upper pillar 232 has a lower end 232a and an upper end 232b. The lower end 232a is in contact with the connection portion 233. The upper end 232b is positioned on a side opposite to the lower end 232a in the Z direction. The upper end 232b is an upper end 55b of the memory pillar 55. The upper end 232b is electrically connected to a bit line BL. In the present embodiment, a width W232a of the lower end 232a in the X direction is larger than a width W232b of the upper end 232b in the X direction. Here, the width W232a of the lower end 232a may be defined as, for example, a width in the X direction of a portion 232s1 of the upper pillar 232 that faces the lowermost conductive layer 61 among the plurality of conductive layers 61 of the upper multi-layered body 51b. Also, the width W232b of the upper end 232b may be defined as, for example, a width in the X direction of a portion 232s2 of the upper pillar 232 that faces the uppermost conductive layer 61 among the plurality of conductive layers 61 of the upper multi-layered body 51b. Therefore, “the width W232a in the X direction of the lower end 232a of the upper pillar 232 is larger than the width W232b in the X direction of the upper end 232b of the upper pillar 232” means, for example, that a width in the X direction of the portion 232s1 of the upper pillar 232 is larger than a width in the X direction of the portion 232s2 of the upper pillar 232.

The upper pillar 232 has a maximum outer diameter portion (maximum width portion) 232m, a first portion 232n1, and a second portion 232n2. The maximum outer diameter portion 232m is a portion whose outer diameter (that is, a width in the X direction or Y direction) is the largest in the upper pillar 232. In the present embodiment, the maximum outer diameter portion 232m is positioned below a center of the upper pillar 232 in the Z direction.

The first portion 232n1 is a diameter reducing portion positioned between the lower end 232a and the maximum outer diameter portion 232m, and in which an outer diameter of the memory pillar 55 reduces downward. The second portion 232n2 is a diameter expanding portion positioned between the upper end 232b and the maximum outer diameter portion 232m, and in which an outer diameter of the memory pillar 55 increases downward. In the upper pillar 232, a length L8 of the second portion 232n2 in the Z direction is larger than a length L7 of the first portion 232n1 in the Z direction.

Then, in the present embodiment, the width W231a in the X direction of the lower end 231a of the lower pillar 231 is larger than the width W232b in the X direction of the upper end 232b of the upper pillar 232. Here, “the width W231a in the X direction of the lower end 231a of the lower pillar 231 is larger than the width W232b in the X direction of the upper end 232b of the upper pillar 232” means, for example, that a width in the X direction of the portion 231s1 of the lower pillar 231 is larger than a width in the X direction of the portion 232s2 of the upper pillar 232.

The connection portion 233 is provided in the insulating layer 62A. The connection portion 233 is disposed between the lower pillar 231 and the upper pillar 232. At the connection portion 233, an outer diameter (for example, a width in the X or Y direction) of the memory pillar 55 is enlarged compared to that of the lower pillar 231 and the upper pillar 232. Note that, the connection portion 233 may be omitted, and the lower pillar 231 and the upper pillar 232 may be directly connected to each other.

According to such a configuration, the dividing portion ST is larger on the upper side and smaller on the lower side when viewed macroscopically. On the other hand, the memory pillar 55 is smaller on the upper side and larger on the lower side when viewed macroscopically. Therefore, the maximum width portion 55m of the memory pillar 55 and the maximum width portion 90m of the dividing portion ST tend to be positioned at different heights in the Z direction. Therefore, it is possible to reduce a distance between the memory pillar 55 and the dividing portion ST. Therefore, a size of the semiconductor storage device 1B can be made smaller.

### Fourth Embodiment

Next, a fourth embodiment will be described. The fourth embodiment is different from the first embodiment in that a width W90a in the Y direction of a lower end 90a of a dividing portion ST is larger than a width W90b in the Y direction of an upper end 90b. Note that, configurations other than those described below are the same as the configurations of the first embodiment.

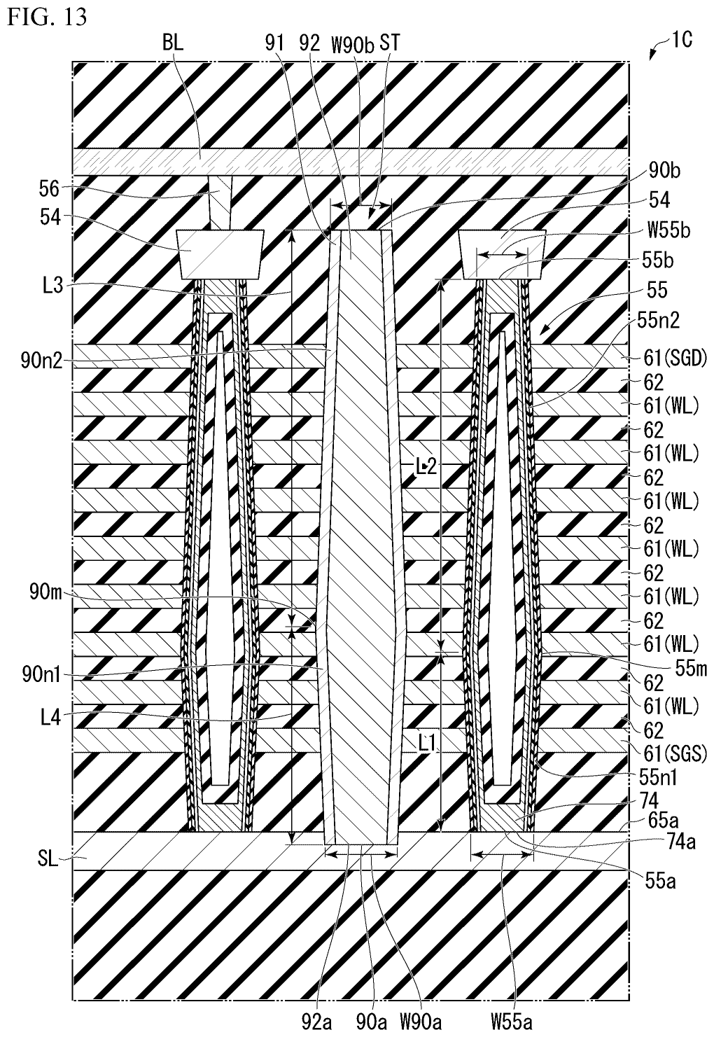

FIG. 13 is a cross-sectional view showing a part of a semiconductor storage device 1C according to the fourth embodiment. In the present embodiment, the dividing portion ST has the lower end 90a and the upper end 90b. The width W90a of the lower end 90a in the Y direction is larger than the width W90b of the upper end 90b in the Y direction. In the present embodiment, a maximum width portion 90m of the dividing portion ST is positioned below a center of the dividing portion ST in the Z direction. Also, a length L4 of a second portion 90n2 in the Z direction is larger than a length L3 of a first portion 90n1 in the Z direction.

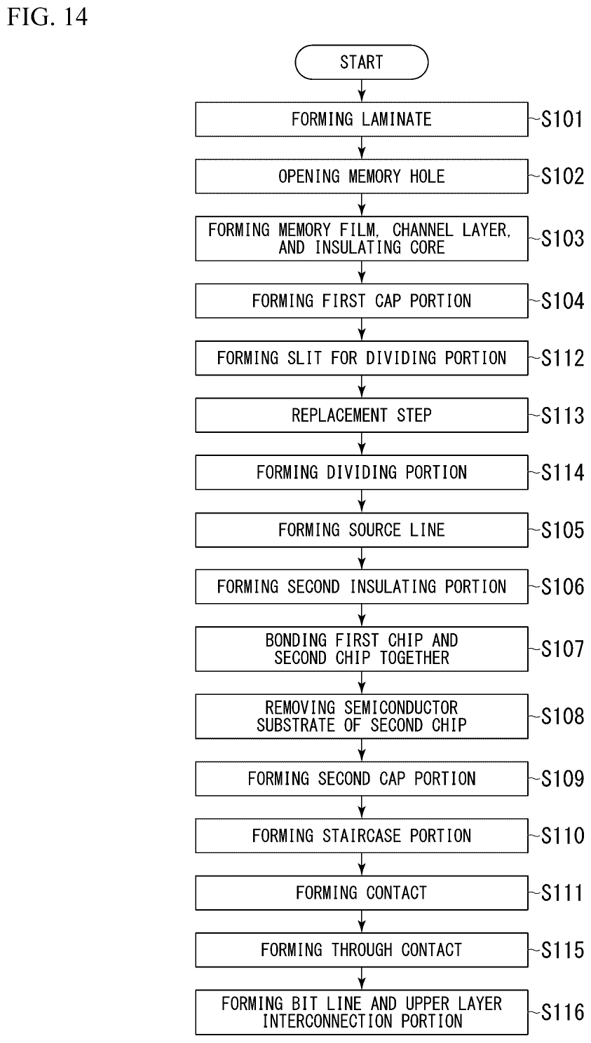

FIG. 14 is a diagram showing a flow of a method of manufacturing a semiconductor storage device 1C of the fourth embodiment. In the present embodiment, before a first chip 2 and a second chip 3 are bonded together, a step of forming a slit 220 in which the dividing portion ST is provided (S112 in FIG. 14), a replacement step of replacing a sacrificial layer 203 with a conductive layer 61 (S113 in FIG. 14), and a step of forming the dividing portion ST inside the slit 220 (refer to S114 in FIG. 14) are performed in the second chip 3. Therefore, when viewed as a completed product of the semiconductor storage device 1C, the dividing portion ST is formed in an inverted tapered shape. Note that, a step of forming a source line SL (S105) may be performed before the step of forming the slit 220 for the dividing portion ST (S112) instead of performing it after the step of forming the dividing portion ST (S114).

According to such a configuration, as in the first embodiment, the source line SL can be formed in a state in which the source line SL is positioned above a multi-layered body 210. Therefore, manufacturability of the semiconductor storage device 1C can be improved.

### Fifth Embodiment

Next, a fifth embodiment will be described. The fifth embodiment is different from the first embodiment in that a multi-layered body 51 does not have a staircase portion 80. Note that, configurations other than those described below are the same as the configurations of the first embodiment.

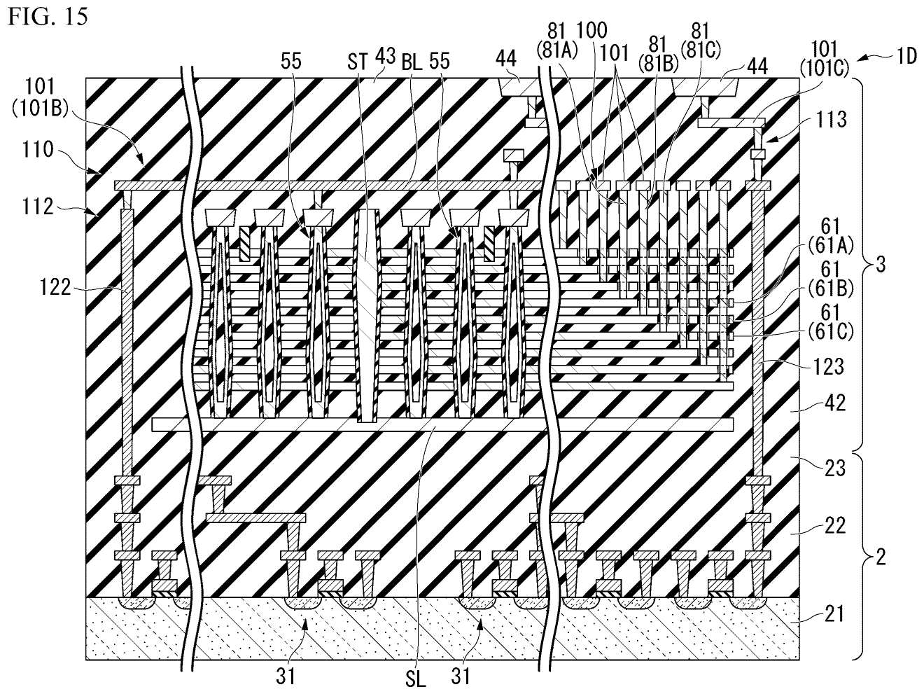

FIG. 15 is a cross-sectional view showing a part of a semiconductor storage device 1D of the fifth embodiment. In the present embodiment, a plurality of conductive layers 61 have the same length in the X direction. In the present embodiment, a plurality of contacts 81 pass through holes penetrating the conductive layers 61 in the Z direction, and extend in the Z direction while maintaining insulation from the conductive layers 61 to which they are not connected. The plurality of contacts 81 extend in the Z direction and have different lengths in the Z direction. A lower end of each contact 81 is in contact with the conductive layer 61 to which it is connected.

According to such a configuration, as in the first embodiment, a source line SL can be formed in a state in which the source line SL is positioned above a multi-layered body 210. Therefore, manufacturability of the semiconductor storage device 1D can be improved.

### Sixth Embodiment

Next, a sixth embodiment will be described. The sixth embodiment is different from the first embodiment in that a staircase portion 80 is provided at a center of a multi-layered body 51 instead of at an end part of the multi-layered body 51. Note that, configurations other than those described below are the same as the configurations of the first embodiment.

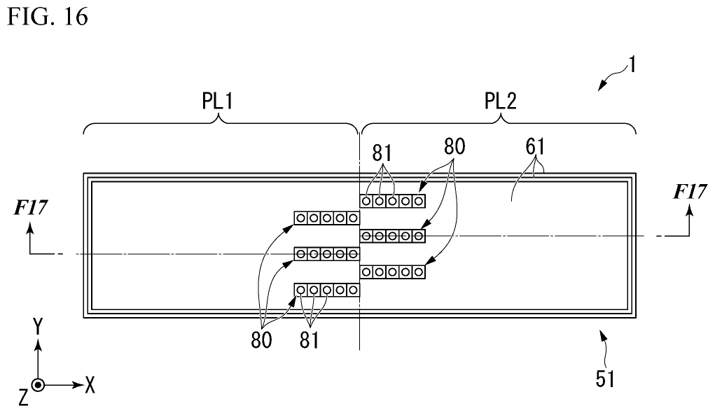

FIG. 16 is a schematic plan view showing a part of a semiconductor storage device 1 according to the sixth embodiment. In the present embodiment, the multi-layered body 51 has a first plane PL1 (first region) and a second plane PL2 (second region). Each of the first plane PL1 and the second plane PL2 has a plurality of conductive layers 61 and a plurality of insulating layers 62 stacked in the Z direction.

In the present embodiment, the staircase portion 80 is provided at the center of the multi-layered body 51 in the X direction. In other words, the staircase portion 80 is provided at an end part of the first plane PL1 adjacent to the second plane PL2 and at an end part of the second plane PL2 adjacent to the first plane PL1. In each of the first plane PL1 and the second plane PL2, the staircase portion 80 is provided only in a part of the multi-layered body 51. The first plane PL1 and the second plane PL2 may be electrically isolated from each other, or may be electrically connected to each other in a region outside the staircase portion 80.

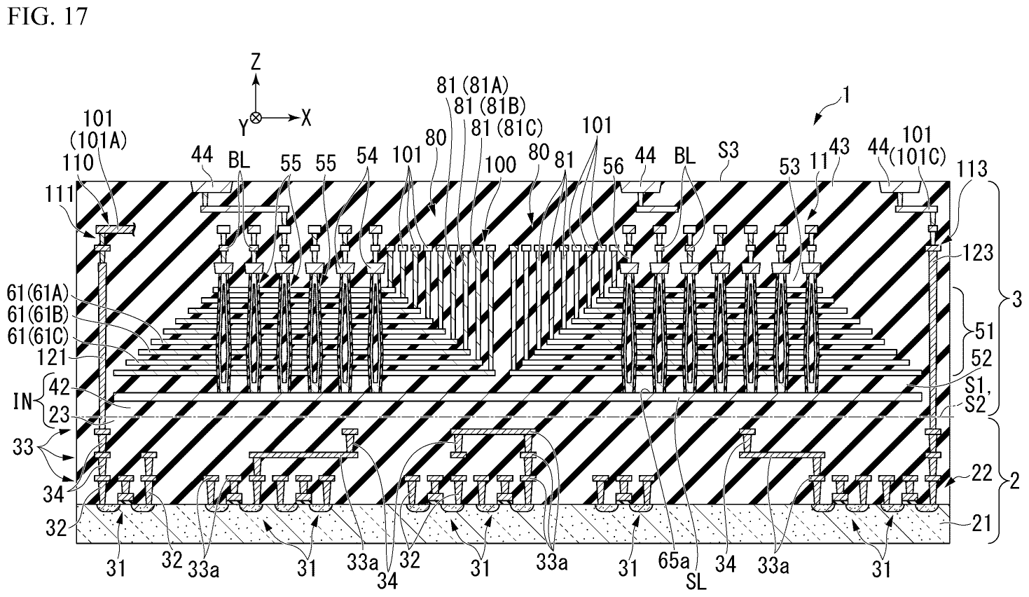

FIG. 17 is a cross-sectional view along line F17-F17 of the semiconductor storage device 1 shown in FIG. 16. In the present embodiment, as described above, the staircase portion 80 is provided at the center of the multi-layered body 51 in the X direction. The plurality of contacts 81 are provided at the center of the multi-layered body 51 in the X direction to correspond to an upper side of the staircase portion 80. The plurality of contacts 81 have different lengths in the Z direction. A lower end of each of the contacts 81 is in contact with a terrace portion of the corresponding conductive layer 61.

For example, the plurality of contacts 81 include a first contact 81A, a second contact 81B, and a third contact 81C. The first contact 81A is provided corresponding to a terrace portion of the first conductive layer 61A and is in contact with the terrace portion of the first conductive layer 61A. The second contact 81B extends further downward than the first contact 81A. The second contact 81B is provided corresponding to a terrace portion of the second conductive layer 61B and is in contact with the terrace portion of the second conductive layer 61B. The third contact 81C extends further downward than the second contact 81B. The third contact 81C is provided corresponding to a terrace portion of the third conductive layer 61C and is in contact with the terrace portion of the third conductive layer 61C.

According to such a configuration, as in the first embodiment, a source line SL can be formed in a state in which the source line SL is positioned above a multi-layered body 210. Therefore, manufacturability of the semiconductor storage device 1 can be improved.

According to at least one of the embodiments described above, a semiconductor storage device includes a substrate, a transistor, a multi-layered body, a pillar, and a source line. The transistor is provided on the substrate. In the multi-layered body, a plurality of gate electrode layers and a plurality of insulating layers are alternately stacked one by one in a first direction. The pillar includes an insulating core, a channel layer, and a memory film. The source line is disposed between the multi-layered body and the substrate, and extends at least in a second direction intersecting the first direction. The pillar has a first end in contact with the source line and a second end positioned on a side opposite to the first end in the first direction. A width of the first end in the second direction is larger than a width of the second end in the second direction. According to such a configuration, manufacturability can be improved.

Hereinafter, some semiconductor storage devices and methods of manufacturing the semiconductor storage devices will be described.
[1] A semiconductor storage device including:
   a substrate;
   a transistor on the substrate;
   a multi-layered body on a side opposite to the substrate with respect to the transistor, including a plurality of gate electrode layers and a plurality of insulating layers which are alternately stacked one by one in a first direction;
   a pillar extending in the first direction within the multi-layered body and including an insulating core, a channel layer disposed between the plurality of gate electrode layers and the insulating core, and a memory film disposed between the plurality of gate electrode layers and the channel layer; and
   a source line between the multi-layered body and the substrate, the source line extending at least in a second direction intersecting the first direction, wherein
   the pillar has a first end and a second end,
   the first end is in contact with the source line,
   the second end is on a side opposite to the first end in the first direction,
   the first end has a width in the second direction, and
   the width of the first end is larger than a width of the second end in the second direction.
[2] In the semiconductor storage device described in [1],
   the source line has a surface facing the multi-layered body, and
   the memory film extends in the first direction within the pillar,
   the memory film is in contact with the surface of the source line, and
   the memory film does not protrude to a side of the substrate beyond the surface of the source line.
[3] In the semiconductor storage device described in [1] or [2],
   the pillar includes a first connection portion,
   the first connection portion is at least between the insulating core and the source line, and
   the first connection portion contains polysilicon.
[4] In the semiconductor storage device described in [1] or [2],
   the source line has a surface facing the multi-layered body,
   the insulating core extends in the first direction within the pillar,
   the insulating core is in contact with the surface of the source line, and
   the insulating core does not protrude to a side of the substrate beyond the surface of the source line.
[5] In the semiconductor storage device described in any one of [1] to [4], a copper pad is not present between the source line and the substrate.
[6] In the semiconductor storage device described in any one of [1] to [5], the source line contains at least one of silicon and tungsten.
[7] The semiconductor storage device described in any one of [1] to [6], further including a bit line on a side opposite to the source line with respect to the pillar, the bit line extending in a third direction intersecting the first direction and the second direction, wherein
   the second end of the pillar is electrically connected to the bit line.
[8] The semiconductor storage device described in [7], further including:
   a peripheral circuit including the transistor; and
   a contact, wherein
   when a side on which the multi-layered body is positioned is defined as an upper side as viewed from the substrate, the contact extends in the first direction from below the source line to above the second end of the pillar,
   the contact electrically connects the peripheral circuit and the bit line.
[9] The semiconductor storage device described in [7] or [8], further including a connection interconnection portion, wherein
   the pillar has a second connection portion,
   the second connection portion is between at least the insulating core and the bit line,
   the second connection portion contains polysilicon,
   the connection interconnection portion includes a plurality of copper interconnections,
   the plurality of copper interconnections are above the second connection portion in the semiconductor storage device, and
   copper interconnections are not present below the second connection portion.
[10] The semiconductor storage device described in any one of [1] to [9], further including a plurality of contacts, wherein
   the plurality of gate electrode layers include a first gate electrode layer, a second gate electrode layer, and a third gate electrode layer,
   the second gate electrode layer is between the first gate electrode layer and the substrate,
   the third gate electrode layer is between the second gate electrode layer and the substrate,
   the plurality of contacts include a first contact, a second contact, a third contact,
   the first contact is in contact with the first gate electrode layer,
   the second contact extends further to a side of the substrate than the first contact,
   the second contact is in contact with the second gate electrode layer,
   the third contact extends further to a side of the substrate than the second contact, and
   the third contact is in contact with the third gate electrode layer.
[11] The semiconductor storage device described in any one of [1] to [10], further including a dividing portion penetrating the multi-layered body in the first direction, the dividing portion extending in the second direction, the dividing portion dividing each of the plurality of gate electrode layers in a third direction intersecting the first direction and the second direction, wherein
   the dividing portion has a third end and a fourth end,
   the third end is in contact with the source line,
   the fourth end is on a side opposite to the third end in the first direction,
   the third end has a width in the third direction, and
   the width of the third end is smaller than a width of the fourth end in the third direction.
[12] The semiconductor storage device described in any one of [1] to [10], further including a dividing portion penetrating the multi-layered body in the first direction, the dividing portion extending in the second direction, the dividing portion dividing each of the plurality of gate electrode layers in a third direction intersecting the first direction and the second direction, wherein
   the dividing portion has a third end and a fourth end,
   the third end is in contact with the source line,
   the fourth end is on a side opposite to the third end in the first direction,
   the third end has a width in the third direction, and
   the width of the third end is larger than a width of the fourth end in the third direction.
[13] A semiconductor storage device including:
   a substrate;
   a transistor on the substrate;
   a multi-layered body on a side opposite to the substrate with respect to the transistor, the multi-layered body including a plurality of gate electrode layers and a plurality of insulating layers, the plurality of gate electrode layers and the plurality of insulating layers being alternately stacked one by one in a first direction;
   a pillar extending in the first direction within the multi-layered body, the pillar including an insulating core, a channel layer, and a memory film, the channel layer being between the plurality of gate electrode layers and the insulating core, the memory film being between the plurality of gate electrode layers and the channel layer; and
   a source line between the multi-layered body and the substrate, the source line extending at least in a second direction intersecting the first direction, wherein
   the source line has a surface facing the multi-layered body, and
   the memory film extends in the first direction within the pillar,
   the memory film is in contact with the surface of the source line, and
   the memory film does not protrude to a side of the substrate beyond the surface of the source line.
[14] A semiconductor storage device including:
   a substrate;
   a transistor on the substrate;
   a multi-layered body on a side opposite to the substrate with respect to the transistor, the multi-layered body including a plurality of gate electrode layers and a plurality of insulating layers, the plurality of gate electrode layers and the plurality of insulating layers being alternately stacked one by one in a first direction;
   a pillar extending in the first direction within the multi-layered body, the pillar including an insulating core, a channel layer, and a memory film, the channel layer being between the plurality of gate electrode layers and the insulating core, the memory film being between the plurality of gate electrode layers and the channel layer; and
   a source line between the multi-layered body and the substrate, the source line extending at least in a second direction intersecting the first direction, wherein
   the pillar includes a first connection portion,
   the first connection portion is at least between the insulating core and the source line, and
   the first connection portion contains polysilicon.
[15] A semiconductor storage device including:
   a substrate;
   a transistor on the substrate;
   a multi-layered body on a side opposite to the substrate with respect to the transistor, the multi-layered body including a plurality of gate electrode layers and a plurality of insulating layers, the plurality of gate electrode layers and the plurality of insulating layers being alternately stacked one by one in a first direction;
   a pillar extending in the first direction within the multi-layered body, the pillar including an insulating core, a channel layer, and a memory film, the channel layer being between the plurality of gate electrode layers and the insulating core, the memory film being between the plurality of gate electrode layers and the channel layer; and
   a source line extending at least in a second direction intersecting the first direction, wherein
   the pillar has a first end and a second end,
   the first end is in contact with the source line,
   the second end is on a side opposite to the first end in the first direction,
   the first end has a width in the second direction,
   the width of the first end is larger than a width of the second end in the second direction, and
   a copper pad is not present between the source line and the substrate.
[16] A semiconductor storage device including:
   a substrate;
   a transistor on the substrate;
   a multi-layered body on a side opposite to the substrate with respect to the transistor, the multi-layered body including a plurality of gate electrode layers and a plurality of insulating layers, the plurality of gate electrode layers and the plurality of insulating layers being alternately stacked one by one in a first direction;
   a pillar extending in the first direction within the multi-layered body, the pillar including an insulating core, a channel layer, and a memory film, the channel layer being between the plurality of gate electrode layers and the insulating core, the memory film being between the plurality of gate electrode layers and the channel layer; and
   a source line extending at least in a second direction intersecting the first direction, and
   a plurality of contacts, wherein
   the pillar has a first end and a second end,
   the first end is in contact with the source line,
   the second end is on a side opposite to the first end in the first direction,
   the first end has a width in the second direction,
   the width of the first end is larger than a width of the second end in the second direction,
   the plurality of gate electrode layers include a first gate electrode layer, a second gate electrode layer, and a third gate electrode layer,
   the second gate electrode layer is between the first gate electrode layer and the substrate,
   the third gate electrode layer is between the second gate electrode layer and the substrate,
   the plurality of contacts include a first contact, a second contact, a third contact,
   the first contact is in contact with the first gate electrode layer,
   the second contact extends further to a side of the substrate than the first contact,
   the second contact is in contact with the second gate electrode layer,
   the third contact extends further to a side of the substrate than the second contact, and
   the third contact is in contact with the third gate electrode layer.
[17] A semiconductor storage device including:
   a substrate;
   a transistor on the substrate;
   a multi-layered body on a side opposite to the substrate with respect to the transistor, the multi-layered body including a plurality of gate electrode layers and a plurality of insulating layers, the plurality of gate electrode layers and the plurality of insulating layers being alternately stacked one by one in a first direction;
   a pillar extending in the first direction within the multi-layered body, the pillar including an insulating core, a channel layer, and a memory film, the channel layer being between the plurality of gate electrode layers and the insulating core, the memory film being between the plurality of gate electrode layers and the channel layer; and
   a dividing portion penetrating the multi-layered body in the first direction, the dividing portion extending in a second direction intersecting the first direction, the dividing portion dividing each of the plurality of gate electrode layers in a third direction intersecting the first direction and the second direction; and
   a source line extending at least in the second direction intersecting the first direction, wherein
   the pillar has a first end and a second end,
   the first end is in contact with the source line,
   the second end is on a side opposite to the first end in the first direction,
   the first end has a width in the second direction,
   the width of the first end is larger than a width of the second end in the second direction, and
   the dividing portion has a third end and a fourth end,
   the third end is in contact with the source line,
   the fourth end is on a side opposite to the third end in the first direction,
   the third end has a width in the third direction, and
   the width of the third end is smaller than a width of the fourth end in the third direction.
[18] A method of manufacturing a semiconductor storage device including:
   preparing a first chip and a second chip, wherein
      the first chip includes:
         a substrate;
         a transistor on the substrate; and
         a first insulating portion covering the transistor, and
      the second chip includes:
         a multi-layered body including a plurality of first layers and a plurality of second layers, the plurality of first layers and the plurality of second layers being alternately stacked one by one in a first direction;
         a pillar extending in the first direction within the multi-layered body, the pillar including an insulating core, a channel layer, and a memory film, the channel layer being between the first layer and the insulating core, the memory film being between the first layer and the channel layer;
         a source line extending at least in a second direction intersecting the first direction; and
         a second insulating portion covering the source line, and wherein
   the method comprises bonding the first insulating portion and the second insulating portion together such that the source line is between the multi-layered body and the first chip.
[19] In the method of manufacturing a semiconductor storage device described in [18], the first layer is a sacrificial layer replaced with a conductive layer after the first insulating portion and the second insulating portion are bonded to each other.
[20] In the method of manufacturing a semiconductor storage device described in [18], the first layer is a conductive layer.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor storage device comprising:
a substrate;
a transistor on the substrate;
a multi-layered body on a side opposite to the substrate with respect to the transistor, the multi-layered body including a plurality of gate electrode layers and a plurality of insulating layers, the plurality of gate electrode layers and the plurality of insulating layers being alternately stacked one by one in a first direction;
a pillar extending in the first direction within the multi-layered body, the pillar including an insulating core, a channel layer, and a memory film, the channel layer being between the plurality of gate electrode layers and the insulating core, the memory film being between the plurality of gate electrode layers and the channel layer; and
a source line between the multi-layered body and the substrate, the source line extending at least in a second direction intersecting the first direction, wherein
the pillar has a first end and a second end,
the first end is in contact with the source line,
the second end is on a side opposite to the first end in the first direction,
the first end has a width in the second direction, and
the width of the first end is larger than a width of the second end in the second direction.

2. The semiconductor storage device according to claim 1, wherein
the source line has a surface facing the multi-layered body,
the memory film extends in the first direction within the pillar,
the memory film is in contact with the surface of the source line, and
the memory film does not protrude to a side of the substrate beyond the surface of the source line.

3. The semiconductor storage device according to claim 1, wherein
the pillar includes a first connection portion,
the first connection portion is at least between the insulating core and the source line, and
the first connection portion contains polysilicon.

4. The semiconductor storage device according to claim 1, wherein
the source line has a surface facing the multi-layered body,
the insulating core extends in the first direction within the pillar,
the insulating core is in contact with the surface of the source line, and
the insulating core does not protrude to a side of the substrate beyond the surface of the source line.

5. The semiconductor storage device according to claim 1, wherein
a copper pad is not present between the source line and the substrate.

6. The semiconductor storage device according to claim 1, wherein
the source line contains at least one of silicon and tungsten.

7. The semiconductor storage device according to claim 1, further comprising
a bit line on a side opposite to the source line with respect to the pillar, the bit line extending in a third direction intersecting the first direction and the second direction, wherein
the second end of the pillar is electrically connected to the bit line.

8. The semiconductor storage device according to claim 7, further comprising:
a peripheral circuit including the transistor; and
a contact, wherein
when a side on which the multi-layered body is positioned is defined as an upper side as viewed from the substrate, the contact extends in the first direction from below the source line to above the second end of the pillar,
the contact electrically connects the peripheral circuit and the bit line.

9. The semiconductor storage device according to claim 7, further comprising a connection interconnection portion, wherein
the pillar has a second connection portion,
the second connection portion is between at least the insulating core and the bit line,
the second connection portion contains polysilicon,
the connection interconnection portion includes a plurality of copper interconnections,
the plurality of copper interconnections are above the second connection portion in the semiconductor storage device, and
copper interconnections are not present below the second connection portion.

10. The semiconductor storage device according to claim 1, further comprising a plurality of contacts, wherein
the plurality of gate electrode layers include a first gate electrode layer, a second gate electrode layer, and a third gate electrode layer,
the second gate electrode layer is between the first gate electrode layer and the substrate,
the third gate electrode layer is between the second gate electrode layer and the substrate,
the plurality of contacts include a first contact, a second contact, a third contact,
the first contact is in contact with the first gate electrode layer,
the second contact extends further to a side of the substrate than the first contact,
the second contact is in contact with the second gate electrode layer,
the third contact extends further to a side of the substrate than the second contact, and
the third contact is in contact with the third gate electrode layer.

11. The semiconductor storage device according to claim 1, further comprising
a dividing portion penetrating the multi-layered body in the first direction, the dividing portion extending in the second direction, the dividing portion dividing each of the plurality of gate electrode layers in a third direction intersecting the first direction and the second direction, wherein
the dividing portion has a third end and a fourth end,
the third end is in contact with the source line,
the fourth end is on a side opposite to the third end in the first direction,
the third end has a width in the third direction, and
the width of the third end is smaller than a width of the fourth end in the third direction.

12. The semiconductor storage device according to claim 1, further comprising
a dividing portion penetrating the multi-layered body in the first direction, the dividing portion extending in the second direction, the dividing portion dividing each of the plurality of gate electrode layers in a third direction intersecting the first direction and the second direction, wherein
the dividing portion has a third end and a fourth end,
the third end is in contact with the source line,
the fourth end is on a side opposite to the third end in the first direction,
the third end has a width in the third direction, and
the width of the third end is larger than a width of the fourth end in the third direction.

13. A semiconductor storage device comprising:
a substrate;
a transistor on the substrate;
a multi-layered body on a side opposite to the substrate with respect to the transistor, the multi-layered body including a plurality of gate electrode layers and a plurality of insulating layers, the plurality of gate electrode layers and the plurality of insulating layers being alternately stacked one by one in a first direction;
a pillar extending in the first direction within the multi-layered body, the pillar including an insulating core, a channel layer, and a memory film, the channel layer being between the plurality of gate electrode layers and the insulating core, the memory film being between the plurality of gate electrode layers and the channel layer; and
a source line between the multi-layered body and the substrate, the source line extending at least in a second direction intersecting the first direction, wherein
the source line has a surface facing the multi-layered body, and
the memory film extends in the first direction within the pillar,
the memory film is in contact with the surface of the source line, and
the memory film does not protrude to a side of the substrate beyond the surface of the source line.

14. A semiconductor storage device comprising:
a substrate;
a transistor on the substrate;
a multi-layered body on a side opposite to the substrate with respect to the transistor, the multi-layered body including a plurality of gate electrode layers and a plurality of insulating layers, the plurality of gate electrode layers and the plurality of insulating layers being alternately stacked one by one in a first direction;
a pillar extending in the first direction within the multi-layered body, the pillar including an insulating core, a channel layer, and a memory film, the channel layer being between the plurality of gate electrode layers and the insulating core, the memory film being between the plurality of gate electrode layers and the channel layer; and
a source line between the multi-layered body and the substrate, the source line extending at least in a second direction intersecting the first direction, wherein
the pillar includes a first connection portion,
the first connection portion is at least between the insulating core and the source line, and
the first connection portion contains polysilicon.

15. A semiconductor storage device comprising:
a substrate;
a transistor on the substrate;
a multi-layered body on a side opposite to the substrate with respect to the transistor, the multi-layered body including a plurality of gate electrode layers and a plurality of insulating layers, the plurality of gate electrode layers and the plurality of insulating layers being alternately stacked one by one in a first direction;
a pillar extending in the first direction within the multi-layered body, the pillar including an insulating core, a channel layer, and a memory film, the channel layer being between the plurality of gate electrode layers and the insulating core, the memory film being between the plurality of gate electrode layers and the channel layer; and
a source line extending at least in a second direction intersecting the first direction, wherein
the pillar has a first end and a second end,
the first end is in contact with the source line,
the second end is on a side opposite to the first end in the first direction,
the first end has a width in the second direction,
the width of the first end is larger than a width of the second end in the second direction, and
a copper pad is not present between the source line and the substrate.

16. A semiconductor storage device comprising:
a substrate;
a transistor on the substrate;
a multi-layered body on a side opposite to the substrate with respect to the transistor, the multi-layered body including a plurality of gate electrode layers and a plurality of insulating layers, the plurality of gate electrode layers and the plurality of insulating layers being alternately stacked one by one in a first direction;
a pillar extending in the first direction within the multi-layered body, the pillar including an insulating core, a channel layer, and a memory film, the channel layer being between the plurality of gate electrode layers and the insulating core, the memory film being between the plurality of gate electrode layers and the channel layer; and
a source line extending at least in a second direction intersecting the first direction, and
a plurality of contacts, wherein
the pillar has a first end and a second end,
the first end is in contact with the source line,
the second end is on a side opposite to the first end in the first direction,
the first end has a width in the second direction,
the width of the first end is larger than a width of the second end in the second direction,
the plurality of gate electrode layers include a first gate electrode layer, a second gate electrode layer, and a third gate electrode layer,
the second gate electrode layer is between the first gate electrode layer and the substrate,
the third gate electrode layer is between the second gate electrode layer and the substrate,
the plurality of contacts include a first contact, a second contact, a third contact,
the first contact is in contact with the first gate electrode layer,
the second contact extends further to a side of the substrate than the first contact,
the second contact is in contact with the second gate electrode layer,
the third contact extends further to a side of the substrate than the second contact, and
the third contact is in contact with the third gate electrode layer.

17. A semiconductor storage device comprising:
a substrate;
a transistor on the substrate;
a multi-layered body on a side opposite to the substrate with respect to the transistor, the multi-layered body including a plurality of gate electrode layers and a plurality of insulating layers, the plurality of gate electrode layers and the plurality of insulating layers being alternately stacked one by one in a first direction;
a pillar extending in the first direction within the multi-layered body, the pillar including an insulating core, a channel layer, and a memory film, the channel layer being between the plurality of gate electrode layers and the insulating core, the memory film being between the plurality of gate electrode layers and the channel layer; and
a dividing portion penetrating the multi-layered body in the first direction, the dividing portion extending in a second direction intersecting the first direction, the dividing portion dividing each of the plurality of gate electrode layers in a third direction intersecting the first direction and the second direction; and
a source line extending at least in the second direction intersecting the first direction, wherein
the pillar has a first end and a second end,
the first end is in contact with the source line,
the second end is on a side opposite to the first end in the first direction,
the first end has a width in the second direction,
the width of the first end is larger than a width of the second end in the second direction, and
the dividing portion has a third end and a fourth end,
the third end is in contact with the source line,
the fourth end is on a side opposite to the third end in the first direction,
the third end has a width in the third direction, and
the width of the third end is smaller than a width of the fourth end in the third direction.

18. A method of manufacturing a semiconductor storage device comprising:
preparing a first chip and a second chip, wherein
the first chip includes:
a substrate;
a transistor on the substrate; and
a first insulating portion covering the transistor, and
the second chip includes:
a multi-layered body including a plurality of first layers and a plurality of second layers, the plurality of first layers and the plurality of second layers being alternately stacked one by one in a first direction;
a pillar extending in the first direction within the multi-layered body, the pillar including an insulating core, a channel layer, and a memory film, the channel layer being between the first layer and the insulating core, the memory film being between the first layer and the channel layer;
a source line extending at least in a second direction intersecting the first direction; and
a second insulating portion covering the source line, and wherein
the method comprises bonding the first insulating portion and the second insulating portion together such that the source line is between the multi-layered body and the first chip.

19. The method of manufacturing a semiconductor storage device according to claim 18, wherein
the first layer is a sacrificial layer replaced with a conductive layer after the first insulating portion and the second insulating portion are bonded to each other.

20. The method of manufacturing a semiconductor storage device according to claim 18, wherein
the first layer is a conductive layer.
